(19) United States
(12) Patent Application Publication
(10) Pub. No.: US 2016/0174420 A1
(43) Pub. Date: Jun. 16, 2016

(54) FORMED CHANNELS PROVIDING ELECTROMAGNETIC SHIELDING IN ELECTRONICS

(71) Applicant: Paul Douglas COCHRANE, Ottawa (CA)

(72) Inventor: Paul Douglas COCHRANE, Kingston (CA)

(21) Appl. No.: 14/899,227

(22) PCT Filed: Mar. 17, 2014
(86) PCT No.: PCT/US2014/030388

§ 371 Date: Dec. 17, 2015

Related U.S. Application Data
(63) Continuation-in-part of application No. 14/104,055, filed on Dec. 12, 2013, now abandoned.
(60) Provisional application No. 61/790,068, filed on Mar. 15, 2013.

(51) Int. Cl. H05K 9/00

(52) U.S. Cl. CPC H05K 9/0009

(57) ABSTRACT

An electronics enclosure comprises a lid and a box made of conductive material, preferably mild steel. Improved electromagnetic interference shielding is provided by forming attenuation troughs in a semi-cylindrical form into both the lid and the box around the periphery of the enclosure. One of the troughs (the female) is formed slightly smaller than the other trough (male) to provide line or multiple point contact along the adjacent surfaces of the shapes. The line and/or multiple point contact between the troughs provides both conductance and capacitance.

### REFERENCE TO PRIORITY DOCUMENTS

This application also claims priority under 35 USC §119(e) to U.S. Provisional Ser. No. 61/790,068, entitled FORMED CHANNELS PROVIDING ELECTROMAGNETIC SHIELDING IN ELECTRONICS ENCLOSURES, filed in the USPTO on Mar. 15, 2013, which is incorporated by reference, in its entirety for all purposes. This application also claims priority to U.S. application Ser. No. 14/104,055, filed Dec. 12, 2013, which is also incorporated by reference for all purposes.

### BACKGROUND

The following background section is, in part, reprinted from “Design Techniques for EMC—Part 4 Shielding” by Eur Ing Keith Armstrong, Cherry Clough Consultants, Associate of EMC-UK.

A complete volumetric shield is often known as a “Faraday Cage”, although this can give the impression that a cage full of holes (like Mr Faraday's original) is acceptable, which it generally is not. There is a cost hierarchy to shielding which makes it commercially important to consider shielding early in the design process. Shields may be fitted around the following: individual ICs—example cost 25 P; segregated areas of PCB circuitry—example cost .English Pound.1; whole PCBs—example cost .English Pound.10; sub-assemblies and modules—example cost .English Pound.15; complete products—example cost .English Pound.100; assemblies (e.g. industrial control and instrumentation cubicles)—example cost .English Pound.1,000; rooms—example cost. English Pound.10,0000; and buildings—example cost .English Pound.100,000.

Shielding always adds cost and weight, so it is always best to use the other techniques described in this series to improve EMC and reduce the need for shielding. Even when it is hoped to avoid shielding altogether, it is best to allow for Murphy's Law and design from the very conception so that shielding can be added later if necessary. A degree of shielding can also be achieved by keeping all conductors and components very close to a solid metal sheet. Ground-planed PCBs populated entirely by low-profile surface mounted devices are therefore are recommended for their EMC advantages.

A useful degree of shielding can be achieved in electronic assemblies firstly, by keeping their internal electronic units and cables very close to an earthed metal surface at all times, and secondly, by bonding their earths directly to the metal surface instead of (or as well as) using a safety star earthing system based on green/yellow wires. This technique usually uses zinc-plated mounting plates or chassis, and can help avoid the need for high values of enclosure SE.

Many textbooks have been written on the subject of how shields work, and it is not intended to repeat them here. However, a few broad concepts will help. A shield puts an impedance discontinuity in the path of a propagating radiated electromagnetic wave, reflecting it and/or absorbing it. This is conceptually very similar to the way in which filters work—they put an impedance discontinuity in the path of an unwanted conducted signal. The greater the impedance ratio, the greater the SE.

At thicknesses of 0.5 mm or over, most normal fabrication metals provide good SE above 1 MHz and excellent SE above 100 MHz. Problems with metal shields are mostly caused by thin materials, frequencies below 1 MHz, and apertures.

It is generally best to allow a large distance between the circuits that are shielded and the walls of their shield. The emitted fields outside of the shield, and the fields that the devices are subjected to, will generally be more “diluted” the larger the shielded volume.

When enclosures have parallel walls opposite each other, standing waves can build up at resonant frequencies and these can cause SE problems. Irregular shaped enclosures or ones with curved or non-parallel walls will help prevent resonances. When opposing shield walls are parallel, it is desirable to prevent resonances from occurring at the same frequencies due to width, height, or length. So, in order to avoid cubic enclosures, rectangular cross-sections can be used instead of square ones, and it is preferable to avoid dimensions that are simple multiples of each other. For example, if the length is 1.5 times the width, the second resonance of the width should coincide with the third resonance of the length. It is preferable to use irrationally ratio'd dimensions, such as those provided by the Fibonacci series.

Fields come in two flavours: electric (E) and magnetic (M). Electromagnetic fields consist of E and M fields in a given ratio (giving a wave impedance E/M of 377 in air). Electric fields are easily stopped by thin metal foils since the mechanism for electric field shielding is one of charge re-distribution at a conductive boundary; therefore, almost anything with a high conductivity (low resistance) will present suitably low impedance. At high frequencies, considerable displacement currents can result from the rapid rate of charge re-distribution, but even thin aluminium can manage this well. However, magnetic fields are much more difficult to stop. They need to generate eddy currents inside the shield material to create magnetic fields that oppose the impinging field. Thin aluminium is not going to be very suitable for this purpose, and the depth of current penetration required for a given SE depends on the frequency of the field. The SE also depends on the characteristics of the metal used for the shield which is known as the “skin effect”.

The skin depth of the shield material known as the “skin effect” makes the currents caused by the impinging magnetic field to be reduced by approximately 9 dB. Hence a material which was as thick as 3 skin depths would have an approximately 27 dB lower current on its opposite side and have an SE of approximately 27 dB for that M field.

The skin effect is especially important at low frequencies where the fields experienced are more likely to be predominantly magnetic with lower wave impedance than 377.OMEGA. The formula for skin depth is given in most textbooks; however, the formula requires knowledge of the shielding material's conductivity and relative permeability.

Copper and aluminium have over 5 times the conductivity of steel, so are very good at stopping electric fields, but have a relative permeability of 1 (the same as air). Typical mild steel has a relative permeability of around 300 at low frequencies, falling to 1 as frequencies increase above 100 kHz. The higher permeability of mild steel gives it a reduced skin depth, making the reasonable thicknesses better than aluminium for shielding low frequencies. Different grades of steels (especially stainless) have different conductivities and permeabilities, and their skin depths will vary considerably as a result. A good material for a shield will have high conductivity and high permeability, and sufficient thickness to achieve the required number of skin-depths at the lowest frequency of concern. 1 mm thick mild steel plated with pure zinc (for instance 10 microns or more) is suitable for many applications.

It is easy to achieve SE results of 100 dB or more at frequencies above 30 MHz with ordinary constructional metalwork. However, this assumes a perfectly enclosing shield volume with no joints or gaps, which makes assembly of the product rather difficult unless you are prepared to seam-weld it completely and also have no external cables, antenna, or sensors (rather an unusual product). In practice, whether shielding is being done to reduce emissions or to improve immunity, most shield performance are limited by the apertures within it. Considering apertures as holes in an otherwise perfect shield implies that the apertures act as half-wave resonant “slot antenna”. This allows us to make predictions about maximum aperture sizes for a given SE: for a single aperture, SE=20 log(.OMEGA./2 d) where .OMEGA. is the wavelength at the frequency of interest and d is the longest dimension of the aperture. In practice, this assumption may not always be accurate, but it has the virtue of being an easy design tool which is a good framework. It may be possible to refine this formula following practical experiences with the technologies and construction methods used on specific products. [0015] The resonant frequency of a slot antenna is governed by its longest dimension—its diagonal. It makes little difference how wide or narrow an aperture is, or even whether there is a line-of-sight through the aperture. [0016] Even apertures, the thickness of a paint or oxide film, formed by overlapping metal sheets, still radiate (leak) at their resonant frequency just as well as if they were wide enough to poke a finger through. One of the most important EMC issues is keeping the product's internal frequencies internal, so they don't pollute the radio spectrum externally.

The half-wave resonance of slot antenna (expressed in the above rule of thumb: SE=20 log(2 d)) using the relationship v=f.lamda. (where v is the speed of light: 3.10.sup.8 metres/sec, f is the frequency in Hz, and is the wavelength in metres). We find that a narrow 430 mm long gap along the front edge of a 19-inch rack unit's front panel will be half-wave resonant at around 350 MHz. At this frequency, our example 19″ front panel is no longer providing much shielding and removing it entirely might not make much difference. For an SE of 20 dB at 1 GHz, an aperture no larger than around 16 mm is needed. For 40 dB this would be only 1.6 mm, requiring the gaskets to seal apertures and/or the use of the waveguide below cut-off techniques described later. An actual SE in practice will depend on internal resonances between the walls of the enclosure itself, the proximity of components and conductors to apertures (keep noisy cables such as ribbon cables carrying digital busses well away from shield apertures and joints) and the impedances of the fixings used to assemble the parts of the enclosure, etc.

Wherever possible, it is desirable to break all necessary or unavoidable apertures into a number of smaller ones. Unavoidably long apertures (covers, doors, etc) may need conductive gaskets or spring fingers (or other means of maintaining shield continuity). The SE of a number of small identical apertures nearby each other is (roughly) proportional to their number (SE=20 log n, where n is the number of apertures), so two apertures will be worse by 6 dB, four by 12 dB, 8 by 18 dB, and so on. But when the wavelength at the frequency of concern starts to become comparable with the overall size of the array of small apertures, or when apertures are not near to each other (compared with the wavelength), this crude 6 dB per doubling rule breaks down because of phase cancellation effects.

Apertures placed more than half a wavelength apart do not generally worsen the SEs that achieves individually, but half a wavelength at 100 MHz is 1.5 metres. At such low frequencies on typical products smaller than this, an increased number of apertures will tend to worsen the enclosure's SE.

Apertures don't merely behave as slot antenna. Currents flowing in a shield and forced to divert their path around an aperture will cause it to emit magnetic fields. Voltage differences across an aperture will cause the aperture to emit electric fields. The author has seen dramatic levels of emissions at 130 MHz from a hole no more than 4 mm in diameter (intended for a click-in plastic mounting pillar) in a small PCB-mounted shield over a microcontroller.

The only really sensible way to discover the SE of any complex enclosure with apertures is to model the structure, along with any PCBs and conductors (especially those that might be near any apertures) with a 3-dimensional field solver. Software packages that can do this now have more user-friendly interfaces and run on desktop PCs. Alternatively, the user will be able to find a university or design consultancy that has the necessary software and the skills to drive it.

Since an SE will vary strongly with the method and quality of assembly, materials, and internal PCBs and cables, it is always best to allow an SE ‘safety margin’ of 20 dB. It may also be advantageous to at least include design-in features that will allow improvement of the SE by at least 20 dB if there are problems with the final design's verification/qualification testing.

The frequency of 50 Hz is problematic, and an SE at this frequency with any reasonable thickness of ordinary metals is desirable. Special materials such as Mumetal and Radiometal have very high relative permeabilities, often in the region of 10,000. Their skin depth is correspondingly very small, but they are only effective up to a few tens of kHz. It is advantageous to take care not to knock items made of these materials, as this ruins their permeability and they have to be thrown away or else re-annealed in a hydrogen atmosphere. These exotic materials are used rather like channels to divert the magnetic fields away from the volume to be protected. This is a different concept to that used by ordinary shielding.

All metals shield materials with relative permeability greater than 1 can saturate in intense magnetic fields, and then don't work well as shields and often heat up. A steel or Mumetal shield box over a mains transformer to reduce its hum fields can saturate and fail to achieve the desired effect. Often, this is all that is necessary to make the box larger so it does not experience such intense local fields. Another shielding technique for low frequency shielding is active cancellation, and at least two companies have developed this technique specifically for stabilizing the images of CRT VDUs in environments polluted by high levels of power frequency magnetic fields.

FIG. 1D shows that if we extend the distance that a wave leaking through an aperture has to travel between surrounding metal walls before it reaches freedom, we can achieve respectable SEs even though the apertures may be large enough to put a first through. This very powerful technique is called “waveguide below cut-off.”Honeycomb metal constructions are really a number of waveguides below cut-off stacked side-by-side, and are often used as ventilation grilles for shielded rooms, similar to high-SE enclosures. Like any aperture, a waveguide allows all its impinging fields to pass through when its internal diagonal (g) is half a wavelength. Therefore, the cut-off frequency of our waveguide is given by: f.sub.cutoff=150,000/g (answer in MHz when g is in mm.) Below its cut-off frequency, a waveguide does not leak like an ordinary aperture (as shown by FIG. 1A) and can provide a great deal of shielding: for f<0.5f.sub.cutoff SE is approximately 27 d/g where d is the distance through the waveguide the wave has to travel before it is free.

FIG. 1A shows examples of the SE achieved by six different sizes of waveguides below cut-off. Smaller diameter (g) results in a higher cut-off frequency, with a 50 mm (2 inch) diameter achieving full attenuation by 1 GHz. Increased depth (d) results in increased SE, with very high values being readily achieved.

Waveguides below cut-off do not have to be made out of tubes, and can be realized using simple sheet metalwork which folds the depth (d) so as not to increase the size of the product by much. As a technique, it is only limited by the imagination, but it must be taken into consideration early in a project as it is usually difficult to retro-fit to a failing product .not intended for use. Conductors should never be passed through waveguides below cut-off, as this compromises their effectiveness. Waveguides below cut-off can be usefully applied to plastic shafts (e.g. control knobs) so that they do not compromise the SE where they exit an enclosure. The alternative is to use metal shafts with a circular conductive gasket and suffer the resulting friction and wear. Waveguides below cut-off can avoid the need for continuous strips of gasket, and/or for multiple fixings, and thus save material costs and assembly times.

Gaskets are used to prevent leaky apertures at joints, seams, doors and removable panels. For fit-and-forget assemblies, gasket design is not too difficult, but doors, hatches, covers, and other removable panels create many problems for gaskets, as they must meet a number of conflicting mechanical and electrical requirements, not to mention chemical requirements (to prevent corrosion). Shielding gaskets are sometimes required to be environmental seals as well, adding to the compromise.

FIG. 1B shows a typical gasket design for the door of an industrial cabinet, using a conductive rubber or silicone compound to provide an environmental seal as well as an EMC shield. Spring fingers are often used in such applications as well.

It is worth noting that the green/yellow wire used for safety earthing of a door or panel has no benefits for EMC above a few hundred kHz. This might be extended to a few MHz if a short wide earthing strap is used instead of a long wire.

A huge range of gasket types is available from a number of manufacturers, most of whom also offer customizing services. This observation reveals that no one gasket is suitable for a wide range of applications. Considerations when designing or selecting gaskets include: (1) mechanical compliance; (2) compression set; (3) impedance over a wide range of frequencies; (4) resistance to corrosion (low galvanic EMFs in relation to its mating materials, appropriate for the intended environment); (5) the ability to withstand the expected rigors of normal use; (6) shape and preparation of mounting surface (7) ease of assembly and dis-assembly; and (8) environmental sealing, and smoke and fire requirements.

There are four main types of shielding gaskets: conductive polymers, conductively wrapped polymers, metal meshes and spring fingers. (1) Conductive polymers (insulating polymers with metal particles in them double as environmental seals, and have low compression set but need significant contact pressure, making them difficult to use in manually-opened doors without lever assistance. (2) Conductively wrapped polymers (polymer foam or tube with a conductive outer coating can be very soft and flexible, with a low compression set. Some only need low levels of contact pressure. However, they may not make the best environmental seals and their conductive layer may be vulnerable to wear. (3) Metal meshes (random or knitted) are generally very stiff but match the impedance of metal enclosures better and so have better SEs than the above types. They have poor environmental sealing performance, but some are now supplied bonded to an environmental seal, so that two types of gaskets may be applied in one operation. (4) Spring fingers (“finger stock”) are usually made of beryllium copper or stainless steel and can be very compliant. Their greatest use is on modules (and doors) which must be easy to manually extract (open), easy to insert (close), and which have a high level of use. Their wiping contact action helps to achieve a good bond, and their impedance match to metal enclosures is good, but when they don't apply high pressures, maintenance may be required (possibly a smear of petroleum jelly every few years). Spring fingers are also more vulnerable to accidental damage, such as getting caught in a coat sleeve and bending or snapping off. The dimensions of spring fingers and the gaps between them causes inductance, so for high frequencies or critical use a double row may be required, such as can be seen on the doors of most EMC test chambers.

Gaskets need appropriate mechanical provisions made on the product to be effective and easy to assemble. Gaskets simply stuck on a surface and squashed between mating parts may not work as well as is optimal—the more their assembly screws are tightened in an effort to compress the gasket and make a good seal, the more the gaps between the fixings can bow, opening up leaky gaps. This is because of inadequate stiffness in the mating parts, and it is difficult to make the mating parts rigid enough without a groove for the gasket to be squashed into, as shown by FIG. 1B. This groove also helps correctly position and retains the gasket during assembly.

Gasket contact areas must not be painted (unless it is with conductive paint), and the materials used, their preparation and plating must be carefully considered from the point of view of galvanic corrosion. All gasket details and measures must be shown on manufacturing drawings, and all proposed changes to them must be assessed for their impact on shielding and EMC. It is not uncommon, when painting work is transferred to a different supplier, for gaskets to be made useless because masking information was not put on the drawings. Changes in the painting processes used can also have a deleterious effect (as can different painting operatives) due to varying degrees of overspray into gasket mounting areas which are not masked off.

FIG. 1C shows a large aperture in the wall of the shielded enclosure, using an internal “dirty box” to control the field leakage through the aperture. The joint between the dirty box and the inside of the enclosure wall must be treated the same as any other joint in the shield.

A variety of shielded windows are available, based on two main technologies: thin metal films on plastic sheets and embedded metal meshes. (1) Thin metal films on plastic sheets, usually indium-tin-oxide (ITO). At film thicknesses of 8 microns and above, optical degradation starts to become unacceptable, and for battery-powered products, the increased backlight power may prove too onerous. The thickness of these films may be insufficient to provide good SEs below 100 MHz. (2) Embedded metal meshes, are usually made of a fine mesh of blackened copper wires. For the same optical degradation as a metal film, these provide much higher SEs, but they can suffer from Moire fringing with the display pixels if the mesh is not sized correctly. One trick is to orient the mesh diagonally.

Honeycomb metal display screens are also available for the very highest shielding performance. These are large numbers of waveguides below cut-off, stacked side by side, and are mostly used in security or military applications. The extremely narrow viewing angle of the waveguides means that the operators head prevents anyone else from sneaking a look at their displays.

The mesh size must be small enough not to reduce the enclosure's SE too much. The SE of a number of small identical apertures near to each other is (roughly) proportional to their number, n, (DSE=20 log n), so two apertures will make SE worse by 6 dB, four by 12 dB, 8 by 18 dB, and so on. For a large number of small apertures typical of a ventilation grille, mesh size will be considerably smaller than one aperture on its own would need to be for the same SE. At higher frequencies where the size of the ventilation aperture exceeds one-quarter of the wavelength, this crude “6 dB per doubling” formula can lead to over-engineering, but no simple rule of thumb exists for this situation.

Waveguides below cut-off allow high air flow rates with high values of SE. Honeycomb metal ventilation shields (consisting of many long narrow hexagonal tubes bonded side-by-side) have been used for this purpose for many years. It is believed that at least one manufacturer of highly shielded 19″ rack cabinets claims to use waveguide below cut-off shielding for the top and bottom ventilation apertures that use ordinary sheet metalwork techniques.

The design of shielding for ventilation apertures can be complicated by the need to clean the shield of the dirt deposited on it from the air. Careful air filter design can allow ventilation shields to be welded or otherwise permanently fixed in place.

Plastic enclosures are often used for a pleasing feel and appearance, but can be difficult to shield. Coating the inside of the plastic enclosure with conductive materials such as metal particles in a binder (conductive paint), or with actual metal (plating), is technically demanding and requires attention to detail during the design of the mould tooling if it is to stand a chance of working.

It is often found, when it is discovered that shielding is necessary, that the design of the plastic enclosure does not permit the required SE to be achieved by coating its inner surfaces. The weak points are usually the seams between the plastic parts; they often cannot ensure a leak-tight fit, and usually cannot easily be gasketted. Expensive new mould tools are often needed, with consequent delays to market introduction and to the start of income generation from the new product.

Whenever a plastic case is required for a new product, it is financially vital that consideration be given to achieving the necessary SE right from the start of the design process.

Paint or plating on plastic can never be very thick, so the number of skin-depths achieved can be quite small. Some clever coatings using nickel and other metals have been developed to take advantage of nickel's reasonably high permeability in order to reduce skin depth and achieve better SE.

Other practical problems with painting and plating include making them stick to the plastic substrate over the life of the product in its intended environment. This is not easy to do without expert knowledge of the materials and processes. Conductive paint or plating flaking off inside a product can do a lot more than compromise EMC—it can short out conductors, causing unreliable operation and risk fires and electrocution. Painting and plating plastics must be done by experts with long experience in that specialized field.

A special problem with painting or plating plastics is voltage isolation. For class II products (double insulated), adding a conductive layer inside the plastic cases can reduce creepage and clearance distances and compromise electrical safety. Also, for any plastic-cased product, adding a conductive layer to the internal surface of the case can encourage personnel electrostatic discharge (ESD) through seams and joints, possibly replacing a problem of radiated interference with the problem of susceptibility to ESD. For commercial reasons, it is important that careful design of the plastic enclosure occurs from the beginning of the design process if there is any possibility that shielding might eventually be required.

Some companies box cleverly (pun intended) by using thin and unattractive low-cost metal shields on printed circuit boards or around assemblies, making it unnecessary for their pretty plastic case to do double duty as a shield. This can save a great deal of cost and headache, but must be considered from the start of a project or else there will be no room available (or the wrong type of room) to fit such internal metalwork.

Volume-conductive plastics or resins generally use distributed conductive particles or threads in an insulating binder which provides mechanical strength. Sometimes these suffer from forming a “skin” of the basic plastic or resin, making it difficult to achieve good RF bonds without helicoil inserts or similar means. These insulating skins make it difficult to prevent long apertures which are created at the joints, and also make it difficult to provide good bonds to the bodies of connectors, glands, and filters. Problems with the consistency of mixing conductive particles and polymers can make enclosures weak in some areas and lacking in shielding in others.

Materials based on carbon fibres (which are themselves conductive) and self-conductive polymers are starting to become available, but they do not have the high conductivity of metal and so do not give as good an SE for a given thickness. The screens and connectors (or glands) of all screened cables that penetrate a shielded enclosure, and their 360.degree. bonding, are as vital a part of any “Faraday Cage” as the enclosure metalwork itself. The thoughtful assembly and installation of filters for unshielded external cables is also vital to achieve a good SE. Refer to the draft IEC1000-5-6 (95/210789 DC from BSI) for best practices in industrial cabinet shielding (and filtering). Refer to BS IEC 61000-5-2:1998 for best practices in cabling (and earthing).

Returning to our original theme of applying shielding at as low a level of assembly as possible to save costs, we should consider the issues of shielding at the level of the PCB. The ideal PCB-level shield is a totally enclosing metal box with shielded connectors and feedthrough filters mounted in its walls, which is in fact just a miniature version of a product-level shielded enclosure as described above. The result is often called a module which can provide extremely high SEs, and is very often used in the RF and microwave worlds.

Lower cost PCB shields are possible, although their SE is not usually as good as a well-designed module. It all depends upon a ground plane in a PCB used to provide one side of the shield, so that a simple five-sided box can be assembled on the PCB like any other component. Soldering this five-sided box to the ground plane at a number of points around its circumference creates a “Faraday cage” around the desired area of circuitry. A variety of standard five-sided PCB-mounted shielding boxes are readily available, and companies who specialize in this kind of precision metalwork often make custom designs. Boxes are available with snap-on lids so that adjustments may easily be made, test points accessed, or chips replaced, with the lid off. Such removable lids are usually fitted with spring-fingers all around their circumference to achieve a good SE when they are snapped in place.

Weak points in this method of shielding are obviously the different variations of apertures such as the following: the apertures created by the gaps between the ground-plane soldered connections; any apertures in the ground plane (for example clearances around through-leads and via holes); and any other apertures in the five-sided box (for example ventilation, access to adjustable components, displays, etc.) Seam-soldering the edges of a five-sided box to a component-side ground plane can remove one set of apertures, at the cost of a time-consuming manual operation.

For the lowest cost, we want to bring all our signals and power into the shielded area of our PCB as tracks, avoiding wires and cables. This means we need to use the PCB equivalents of bulkhead-mounting shielded connectors and bulkhead-mounting filters.

The PCB track equivalent of a shielded cable is a track run between two ground planes, often called a “stripline.” Sometimes guard tracks are run on both sides of this “shielded track” on the same copper layer. These guard tracks have very frequently via holes bonding them to the top and bottom ground planes. The number of via holes per inch is the limiting factor here, as the gaps between them act as shield apertures (the guard tracks have too much inductance on their own to provide a good SE at high-frequencies). Since the dielectric constant of the PCB material is roughly four times that of air, when FIGS. 1A-1E are used to determine via spacing, their frequency axes should be divided by two (the square root of the PCB's dielectric constant). Some designers don't bother with the guard tracks and just use via holes to “channel” the track in question. It may be a good idea to randomly vary the spacings of such rows of via holes around the desired spacing in order to help avoid resonances.

Where striplines enter an area of circuitry enclosed by a shielded box, it is sufficient that their upper and lower ground planes (and any guard tracks) are bonded to the screening can's soldered joints on both sides close to the stripline.

The track which only has a single ground plane layer parallel, the other side being exposed to the air, is said to be of “microstrip” construction. When a microstrip enters a shielded PCB box, it will suffer an impedance discontinuity due to the wall of the box. If the wavelength of the highest frequency component of the signals in the microstrip is greater than 100 times the thickness of the box wall (or the width of box mounting flange), the discontinuity may be too brief to register. But where this is not the case, some degradation in performance may occur and such signals are best routed using striplines.

All unshielded tracks must be filtered as they enter a shielded PCB area. It is often possible to get valuable improvements using PCB shielding without such filtering, but this is difficult to predict. Therefore, filtering should always be designed-in (at least on prototypes, only being removed from the PCB layout after successful EMC testing).

The best filters are feedthrough types, but to save cost it is advantageous to avoid wired types. Leaded PCB-mounting types are available and can be soldered to a PCB in the usual manner. Then the leaded PCB mount is hand-soldered to the wall of the screening box when it is fitted at a later stage. Quicker assembly can be achieved by soldering the central contact of the filter to the underlying ground plane, making sure that solder joints between the shielding box and the same ground plane layer are close by on both sides. This latter construction also suits surface-mounted “feed-through” filters, further reducing assembly costs.

But feed-through filters, even surface mounted types, are still more expensive than simple ferrite beads or capacitors. To allow the most cost-effective filters to be found during development EMC testing, whilst also minimizing delay and avoiding PCB layout iterations, multipurpose pad patterns can easily be created to take any of the following filter configurations: (1) zero-ohm link (no filtering, often used as the starting point when EMC testing a new design); (2) a resistor or ferrite bead in series with the signal; ((3) a capacitor to the ground plane; (4) common-mode chokes; (5) resistor/ferrite/capacitor combinations (tee, LC, etc. see Part 3 of this series for more details); (6) feed-through capacitor (i.e. centre-pin grounded, not truly feed-through) and; (7) feedthrough filter (tee, LC, etc., center-pin grounded, not truly feedthrough). Multipurpose padding also means the invention not restricted to proprietary filters and be created to best suit the requirements of the circuit (and the product as a whole) at the lowest cost.

In finding EMI/EMC solutions, the existing technology is inelegant and cumbersome. For example, the prior art uses spoons, which are these little projections with dimples in them that stick out; so that they go into compression and go opposite. One goes over the other so that they go together and they have to make physical contact. These structures bend and when one of them bends at a plane and they don't make contact anymore, they lose their electrical conduct. Then the prior art starts to have EMI leaks. They become tolerance nightmares and they're expensive. In addition, prior art manufacturing techniques designed to counter these problems requires forming the enclosure so that it has to have a tongue and groove or other prohibitive solutions.

Shielding is the use of conductive materials to reduce EMI by reflection or absorption. Shielding electronic products successfully from EMI is a complex problem with three essential ingredients: a source of interference, a receptor of interference, and a path connecting the source to the receptor. If any of these three ingredients is missing, there is no interference problem. Interference takes many forms such as distortion on a television, disrupted/lost data on a computer, or “crackling” on a radio broadcast. The same equipment may be a source of interference in one situation and a receptor in another.

Currently, the FCC regulates EMI emissions between 30 MHz and 2 GHz, but does not specify immunity to external interference. As device frequencies increase (applications over 10 GHz are becoming common), their wavelengths decrease proportionally, meaning that EMI can escape/enter very small openings (for example, at a frequency of 1 GHz, an opening must be less than ½ inch). The trend toward higher frequencies therefore is helping drive the need for more EMI shielding. As a reference point, computer processors operate in excess of 250 MHz and some newer portable phones operate at 900 MHz.

Metals (inherently conductive) traditionally have been the material of choice for EMI shielding. In recent years, there has been a tremendous surge in plastic resins (with conductive coatings or fibers) replacing metals due to the many benefits of plastics. Even though plastics are inherently transparent to electromagnetic radiation, advances in coatings and fibers have allowed design engineers to consider the merits of plastics.

As a specific example, considering the FCC regulation to shield up to 2 GHz, a typical maximum clock speed in many of the controllers in the enterprise networks would be 400 MHz. If you consider the 2 GHz value as the maximum frequency of interest, then at 400 MHz, the user will shield up to and including the 5th harmonic of a 400 MHz signal . . . i.e. 400 MHz*5=2 GHz (shielding to the 5th harmonic of maximum clock speed of 400 MHz). To determine the wavelength at 2 GHz, utilize equation C, above: f.lamda.=c, .lamda.=c/f.lamda.=(3.times.108)/(2*109.lamda.=0.15 meters (at 2 GHz). Terms A & B are of interest regarding the determination of a longest possible slot length .lamda./2=0.075 m or 75 mm. It is recommended that the apertures be kept to a range of approximately .lamda./20 to .lamda./50, therefore for 2 GHz, the apertures should be in the range of: .lamda./20=0.0075 meters or 7.5 mm maximum @ 2 GHz; .lamda./50=0.003 meters or 3.0 mm minimum @ 2 GHz.

### SUMMARY OF THE INVENTION

The present invention removes the need for the single most expensive and least reliable aspect of the electro-mechanical packaging, which is the EMI gasket. The solution(s) provided by the present invention will eliminate the need for gaskets in a great number of applications, as well as “spoons” and other similarly troublesome structures in the PC Chassis and other electronics enclosures. The present invention provides a configuration of placing two and three dimensional formations into and across the seams of a four-by-two or four-by-one-by-one six sided enclosure, in which the 2D and 3D shapes, which are easily formed in conductive metal (or conductive polymers) allow for improved EMI shielding, but also decrease assembly and manufacturing costs (especially in preferred embodiments). In a primary embodiment, there is a lid-and-box enclosure each with an EMI attenuation trough. These EMI attenuation troughs are generally of a male semi cylinder inside a female semi cylinder running the length (or a significant length of the enclosure). These merged structures provide both necessary conductance and capacitance for effective EMI attenuation.

### BRIEF DESCRIPTION OF THE DRAWINGS

FIGS. 1A-1E illustrate various electromagnetic interference shielding principles;

FIG. 2A illustrates a sample pattern in an enclosure as may be implemented in the invention that embodies the principle of “effective length;”

FIG. 2B illustrates a side of a computer enclosure in another embodiment of the invention, or three cuts in the “four-cut” or TORTURED PATH.™. solution; and

FIG. 3 illustrates a two-dimensional embodiment;

FIG. 4 illustrates a simple electronics enclosure for a three-dimensional EMI shielding solution using partial spheres or “scallops”;

FIG. 5A illustrates a 2-d/3-d hybrid of the invention;

FIG. 5C illustrates a feature of a 2d/3d embodiment, using semi-cylinder-in-semi-cylinder formation from an angled view;

FIG. 5D illustrates the semi-cylinder-in-semi cylinder feature from a side view;

FIG. 6A is a main embodiment of the box and cover using attenuation troughs;

FIG. 6B is a view of the box and cover

FIG. 6C is detail of a section of the box;

FIG. 7A is a first illustration of the main embodiment;

FIG. 7B is a second view of the main embodiment;

FIG. 7C is a third view of the main embodiment;

FIG. 8A is a schematic detail of the attenuation trough features of the invention before merging box and cover;

FIG. 8B is a schematic detail of the attenuation trough features when box and cover are merged;

FIG. 9A is a first alternate configuration of the box and cover with a continuous attenuation trough on each side;

FIG. 9B is a second alternate configuration with a continuous attenuation trough behind the attachments;

FIG. 9C is a third alternate configuration of the box and cover with continuous troughs straddling the attachments;

FIG. 9D is a fourth alternate configuration of the box and cover with both continuous and intermittent attenuation troughs;

FIG. 9E is a fifth alternate configuration of the box and cover with a “picture frame” continuous attenuation trough;

FIG. 10 is a configuration of multiple attenuation troughs as they would be placed in parallel; and

FIG. 11 illustrates a variation of the attenuation troughs in which they have embedded or multiple troughs.

### DETAILED DESCRIPTION OF THE DRAWINGS

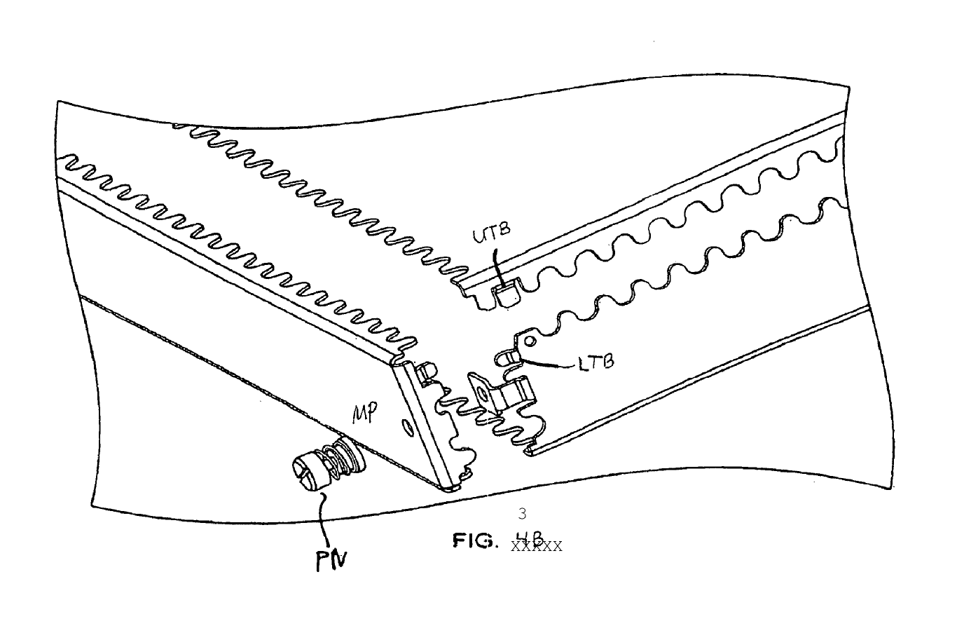

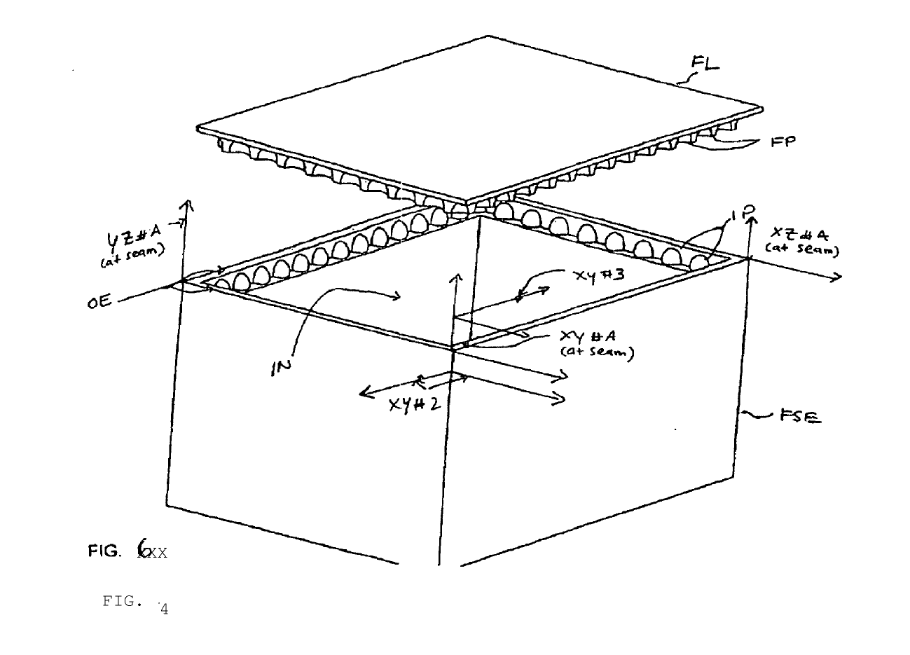

In an embodiment of The TORTURED PATH™ EMI solution is shown for enclosures that are generally in the shape of boxes and other types of cabinets for computers and other electronic components that require EMI/EMC shielding. Referring to FIG. 2A, a principal wall of an enclosure is shown which is the wall of a shielded enclosure made of a conductive material, with the greater sizes of apertures causing a greater amount leakage of the electromagnetic fields. In an embodiment of the invention known by the trade name of “TORTURED PATH™” the improvement reduces the size of apertures by strategically cutting, forming, molding, extruding, stamping and forming any manufacturing method which utilizes an electromagnetically conductive material in basically any application.

The present invention provides a less expensive EMI shielding solution than the way the current technology is implemented. This can be accomplished in various embodiments of the invention implemented “two” dimensions (namely two-dimensional considerations since nothing literally takes place in only two dimension) with sheet metal or flat extruded cut or stamped materials. The material could be cast, again, with a thin sheet metal—assuming that the structures cast, cut, or extruded are thin relative to the overall dimensions, considering that the so-called two-dimensional considerations have finite thickness. As the manufacturing goes into a molding process or casting, it creates a more even three-dimensional shape or forms metal out of the 2D planes and uses drying techniques to create overlaps and further “torture the path.” Thus, a goal of this particular embodiment of the invention is to create small apertures. More particularly, the goal of this embodiment is to create apertures that are not only small but force the electromagnetic noise to change directions or to go through apertures that are small and make the path difficult for the EMI to find its way out (thus, the “tortured path.”) This, of course, reciprocally applies to the susceptibility of the electronics inside the enclosure to electromagnetic interference from the outside as well. EMI, electromagnetic inference generally refers to what is projected outwards to the world and how it might interfere with other devices. However, for the purposes of this disclosure, the expression “EMI” also includes shielding from any devices that are external to the user and that are radiating electromagnetic fields which will cause interference on the product and this is where the user would be susceptible to EMI.

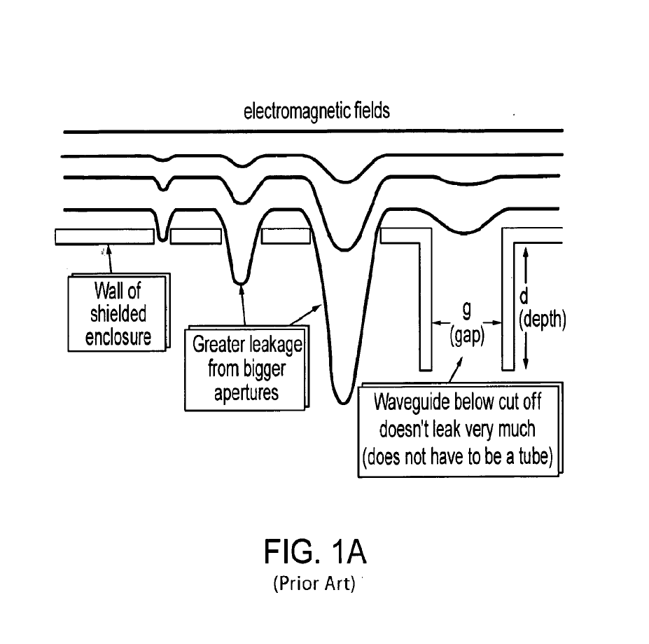

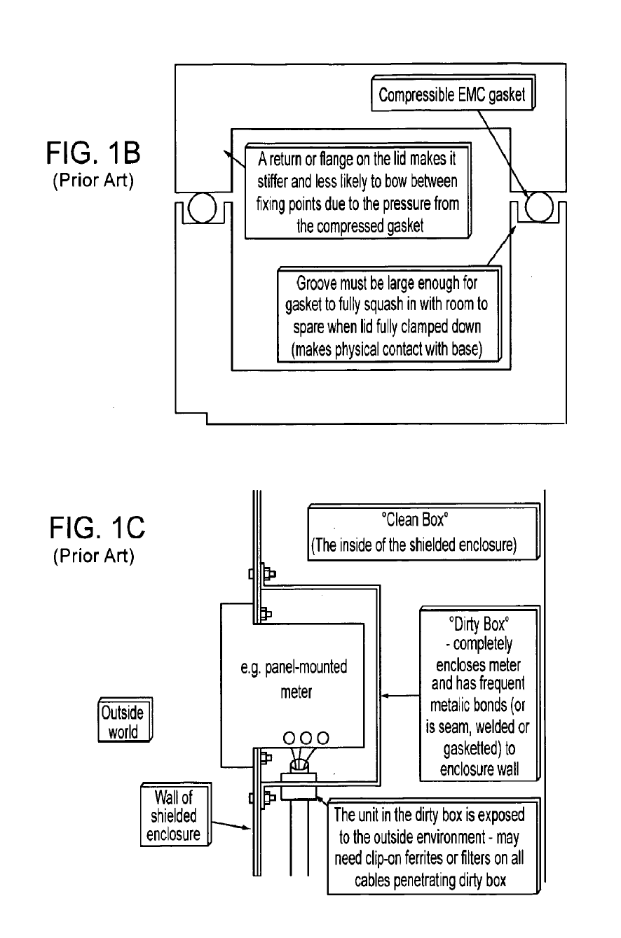

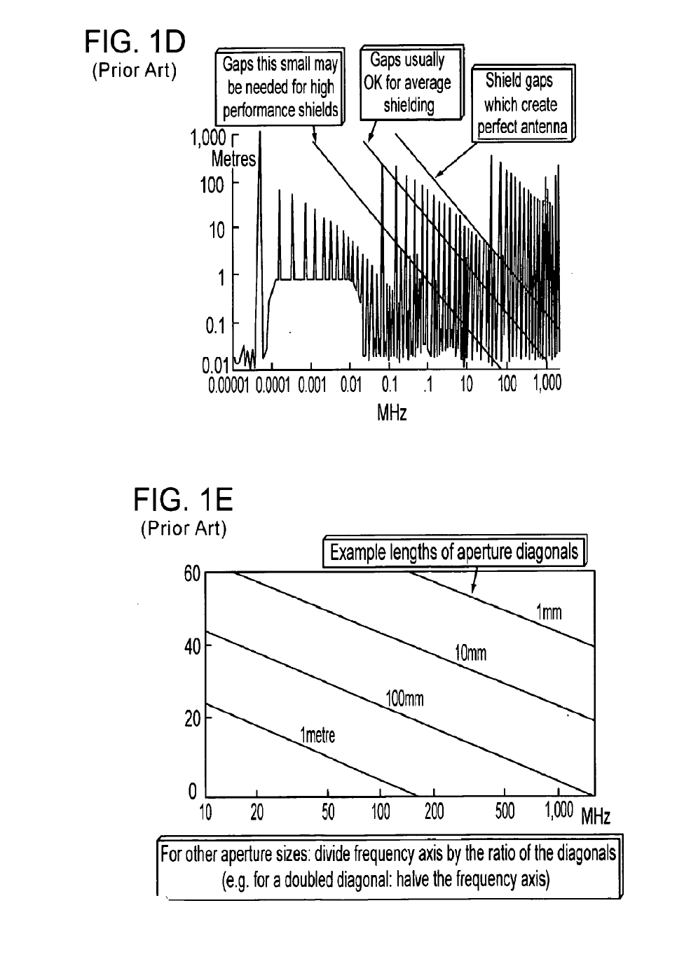

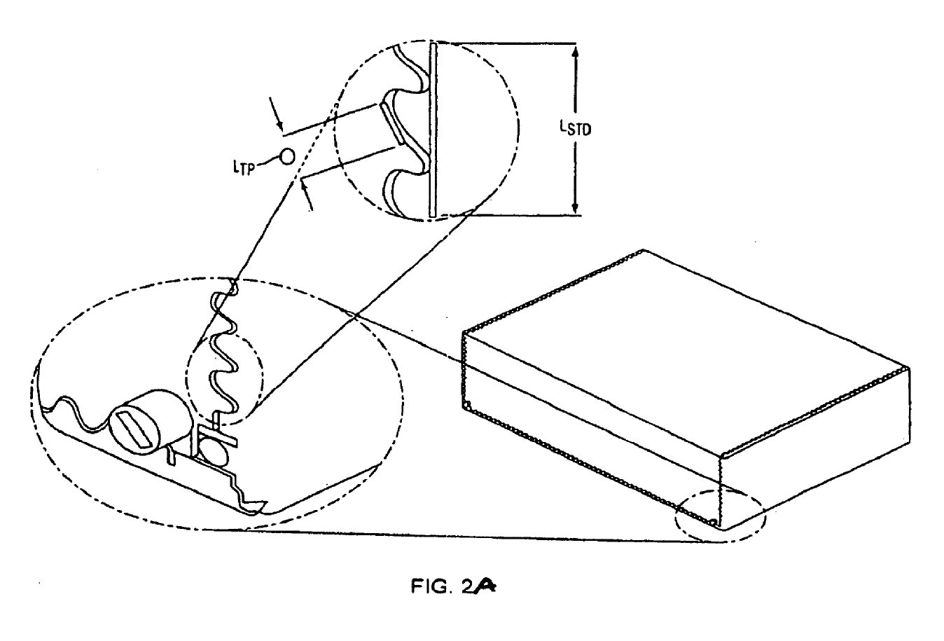

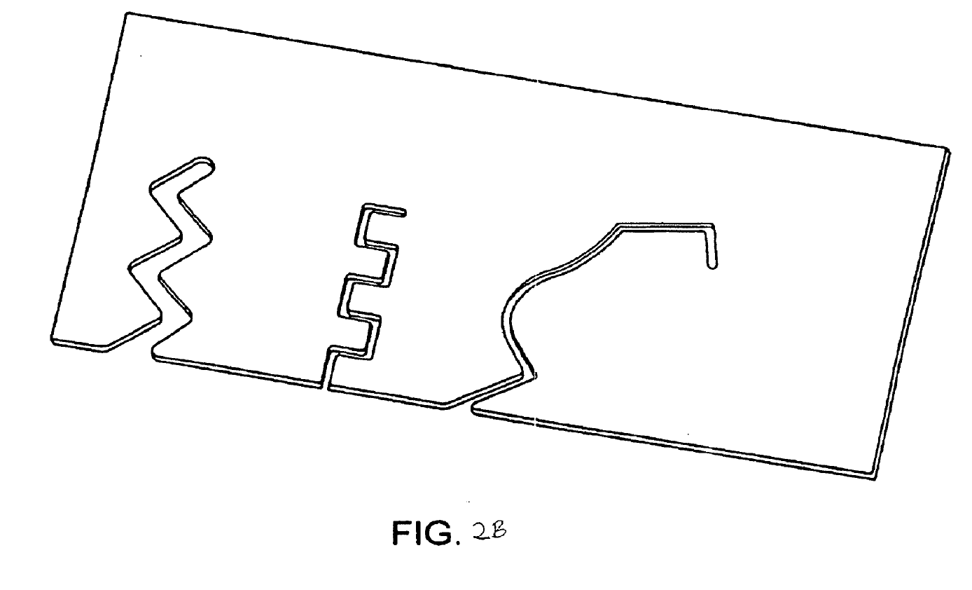

“Wave guides” are discussed above in FIGS. 1A-E, in which the depth of a channel or depth of an aperture causes an increased difficulty for the electromagnetic wave to get out for any given aperture size. The TORTURED PATH.™. invention is implemented in a mold or a cast to create a three-dimensional pathway that does not allow EMI to escape or enter the enclosure, which may include a wave guide effect. But, again, the preferred and conceptually most effective tortured path for the EMI is a sinusoidal saw-tooth square wave, as shown in FIG. 2B, but also may be any kind of irregular shape, whether the pattern is periodic, periodic and changing, or constantly changing in shape. However, the invention requires that the pattern not allow for the maximum aperture size to be sufficient for the electromagnetic waves to traverse through the material, whether it is inward or outward. This principle of the invention is shown in FIG. 2A as “effective length matters.”

Additionally, near 100% reliability is possible in the performance with particular embodiments of the invention, because the medium is not vulnerable to compression or degradation over time. Additionally, there is not any material used as a gasket that will be ripped off and sheared, nor is there a gasket that will plastically deform. Beryllium copper, for example, can plastically deform. Additionally, any metal gasket, finger gaskets or finger stock can either deform through improper design or improper handling, whether that be in shipping or other in situations. Instead, by creating cuts or through two or three-dimensional cuts that control the EMI as a way to control the aperture size, there is nothing to deform. Furthermore, in the present invention, there is no requirement for physical contact, therefore there are no tolerance issues, deforming issues, no degradation over time and no environmental impact. There are no loose structures added. The invention provides an extremely cost effective EMI shielding solution because there are no added parts, no fasteners and no welds. Free-plated material may be used everywhere which are formed in the case of sheet metal, stamp and form and/or a few rivets which do not depend on contact which have no degradation over time and no environmental impact.

Very short wavelengths or very small aperture sizes are allowed in this way but do not require anything other than a stamp and a form. In a case of a mold, it is possible to run that much tighter. It may be narrower than 30,000, in sheet metal. That's very generous and it makes an almost perfect assembly. It is possible to reduce it to 10 or 15 thousandths and there would be no issue. This remains true if all of the cuts are retained so that they're not visible and, if its not exactly the male and female, which don't fit exactly following each other, as long as they stay within that gap, it may be slightly irregular. For example, one peak might be a little close to the valley, but it won't cause interference and, perhaps, it could even cause an intermittent contact which might enhance the electro-conductivity.

Looking at FIG. 2A, the first model of tortured path as shown in “effective length,” a model is shown where the LSTD is the old standard length of a slot. If it was a straight slot, that gap would be, as shown, compared to length of the tortured path, which is the longest straight line distance that the electromagnetic interference can see through the sinusoid. The length standard and the strength slot would be somewhere in the order of eight to 10 times the length of the tortured path. And all that has been done is a stamp and then a subsequent form or stamp, which is brings the male and female image of these two slots together. This is achieved alternately with a small width and large width so the smaller male fits inside the larger female, back and forth, whether that's saw-tooth, square wave, sign wave or some intermittent pattern of those and other shapes. As shown, it is possible to reduce that effective length economically and efficiently at virtually no cost.

FIG. 2B illustrates an alternate and illustrative embodiment of the invention, known by the trade name of The TORTURED PATH.™. EMI solution. Three cuts are shown in various shapes in the illustration, and four are used in a first type of the alternate embodiment. However, the cuts may all be of one type of cut, in appropriate patterns, such as sinusoidal, square wave, and certain Brownian-motion type cuts. The TORTURED PATH.™. EMI solution provides a potentially complete EMI shielding solution in alternate embodiments as long as the four lines are placed to prevent any “snaking” of the sinusoidal wave propagation WP. FIG. 2B shows a couple examples of the different types of shapes. A triangular saw tooth-type cut configuration is shown. Again, the wave(s) are not able to seen by the peaks so it will look for the straightest line it can find. So its just “tortured” in that it cannot see around the corners. The square wave is then seen and then a very odd bent paperclip-looking shape wave, a cut is seen. Any cut imaginable can be used. The goal is to try to reduce the effective length of any slot that can be used as antenna by the electromagnetic interference. So this can be used around I/O devices. This can be used in sheet metal. This can be used in extruded, molded or casted cuts in any shape. It may be used in sort of a modular into a chassis or around the back phalange of a model. It may be used around the input/output devices, in any manufacturing method or in any electromagnetically conducted materials for which EMI needs to be contained. The TORTURED PATH.™. solution reduces the effective length by strategic cuts, shapes or molds or extruded shapes and, in addition, goes three-dimensional through drawing and overlapping, again, torturing the path. Even bringing together a wave-guided effect, The TORTURED PATH.™. is the essence of the invention and it can efficiently be implemented in the present invention with complementary forming techniques or molding techniques that don't require additional costs.

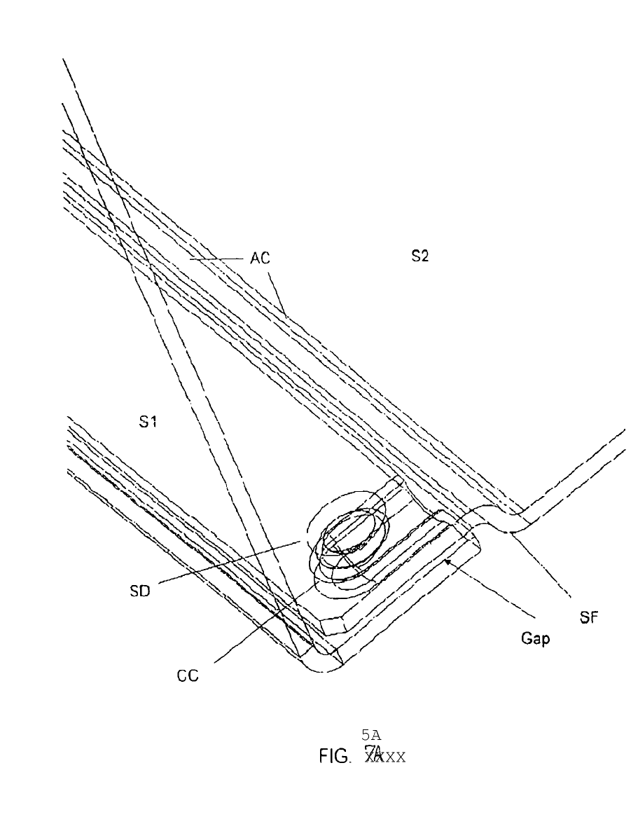

FIG. 3 is a top view of a pure two-dimensional embodiment, a three-sided and three-sided bar where the one three-sided fitting is down over the other and it comes straight down from the top. Then, the EMI/EMC is just deflected in front and back in order to overcome any interference between the sign waves. So it is possible to bring the two U-sections together, having The TORTURED PATH.™. seam running along six different edges to bring the two three-sided boxes or sections together. In the configurations shown in FIG. 3, the ‘nose’ or the front faceplate goes over all four sides and can be tapped and can control the entire assembly In this way, it is possible to actually put the lid down in a configuration where it is actually hooked rotating, in a tongue and groove kind of hook. It is possible to bring it down and capture all the assembly strictly with the faceplate. Basically, there would then be a stamp, a form, a friction fit and then just the lid would be captured. The sides and the base would be captured by the nose cone. In this way, the entire assembly is brought together. While such a process may not provide all the structural integrity that was needed for all end-uses, in many cases it would certainly be adequate. There are many configurations for which this could be done. The EMI can be contained and basically element fasteners eliminate welds and gaskets at a very low cost and additionally provide thermal enhancement. So it would therefore be additionally cost reductive and, thermally enhanced because of the ability to now open up more apertures and would be environmentally friendly, without any addition there. One hundred percent of this is assemble-able and 100% reliable with no degradation over time. It could be quarter turn, but in this case, a simple captive-spring loaded screw that can be taken into a pem-nut on the back of a phalange is pivoted off of the side wall. One of those is at the front and both ends of the chassis where there may a split shear on the one side and just the positive locking on the other.

In the sample two-dimensional configuration, the phalanges come down from the top to the sides and back. In this way, when the lid is off, there is a wide-open exposure to fully populate the inside of the box without any interference. None of the top view looks downwards and it is not covered by any material. Therefore, there is full access to the box. In addition, this could also be done as a four sided box and a two sided box where the top is included as part of the whole front. This could also be done in a two-part assembly instead of three. In the case of a 5.times.1 type of the embodiment, this configuration is very straightforward. This embodiment may also be implemented as a two-part assembly and a 3.times.3 channel box which is also a two-part assembly. Thus, 5.times.1, 4.times.1.times.1, 4.times.2, 3.times.3, 3.times.2.times.1, 3.times.1.times.1.times.1 are all assembly configurations contemplated by the invention. (A 3.times. component is shown in US Application Publication 2006-96773 (assigned to the present application) and can be used in 3.times.3, 3.times.2.times.1, 3.times.1.times.1.times.1 applications, and designed for the specific needs of the end user and other manufacturing requirements in addition to retrofit considerations). FIG. 3 shows an exploded view, respectively of the same front corner of the 17½ inch (in a preferred embodiment, but dimensions are dependent on end-use) 1-RU box and it shows how the tongue tabs UTBs and LTBs would over-lock and interlock with one another. In this way, the tabs bring the entire assembly together, which is sort of a tongue and groove style. An excellent assembly for minimizing fasteners would help to align the chassis and could bring some electrical contacts together, although it is not dependent on this alignment for an appropriate EMI level. Also, here it uses captive fasteners, both in the screw or the retaining screw. Additionally, there is a pem-nut PN, which is mounted to the back of the mounting phalange MP. This shows that once stamped and formed the features are very simple and provided at a very low cost. This is a highly effective manner for fabricating, assembling, and maintaining EMI which is a low cost, high performance and excellent solution.

FIGS. 2A-3 illustrate that the two-dimensional solutions provided in the computer enclosure applications of the present invention can be implemented with ease in all major manufacturing methods including: stamped, laser cut, cast, extruded, molded, etc. In each manufacturing method, almost all of the benefits of each (detailed above) will apply. Because there is a “gap” between mating components, the tolerances in the fabrication process are as “liberal” as possible. The liberal tolerances further accentuate reliability and ensure the highest possible yield of parts off the manufacturing line, so that generally, there are no fit issues. Further, the “one-hit” TORTURED PATH.™. solution can improve packaging flexibility and thermal performance as well. For example, the inventive solution may be used not only for chassis fabrication, but also for modules, FRUs, connectors and other I/O components that require EMC protection/shielding. The inventive solution to cut shapes to provide great open areas for airflow, does not adversely impact the EMI performance and leads to the conclusion that manufacturing cost remains low, while thermal performance remains high.

In FIGS. 2a-3, a preferred two-dimensional embodiment has a diameter of 0.18 and 0.24 inches. The diameter is 0.18″ and the values are at 0.24″. But the dimensions are details that must be optimized depending on end-use which is not something that is required for implementation of the present invention. For two gigahertz, the rule of thumb is between a three millimeter and seven millimeter gap. When using 0.18 and 0.24, it is about six millimeters. In general, forty-two thousandths is a standard gage for a “z-axis” dimension. However, such a dimension is not relevant to the spirit of the present invention, rather a random choice and one that is used frequently by skilled artisans for purposes of convenience and economy. But if one follows this path, it is a 0.24 diameter and one probably ends up close to a diameter. If the two parts together are put together, the slot would probably come very close to the diameter. Finally, when examined from up one side and over the other, the straight line is seen, it would be about six millimeters, which keeps it inside the desired range in a preferred embodiment for a purely two-dimensional EMI shielding solution.

To effectively implement the EMI shielding features of the two-dimensional shielding solutions in a preferred embodiment, if the apertures are cut with maximum efficiency, the EMI will be without any antennae that it needs to radiate, even though the thermals will open up (hopefully not at the cost of EMI performance).

Similar to enhancing thermals, lowering costs relative to gaskets, screws, welds, etc. is one hundred percent reliable. There's absolutely no reliability degradation over time. When these two things are brought together, there's an air gap. There are no compression setting gaskets. There is no deforming or bending of beryllium copper. There is no separating of foam over fabric gaskets, which separate. They are sheared, they separate, and they're bonded with adhesive or something similar. When they are sheared, they may fail. The compression is set over time and they lose performance over time.

Assembly is simplified because there are no welds necessary or any post-operations. When welding is part of the process, there must also be post-plating because it is not possible to weld pre-plate. It would ruin the plating. Otherwise, if there is a weld and then the post-plate, the whole thing must be mapped. The problem is, if there is a map with a post-plate, if there are any hems, the result is entrapment; with entrapment, there exists a source for oxidation. So if the plating material is entrapped, it just sits there in the gap, or it doesn't get in at all. It either gets entrapped or it doesn't penetrate and if there is enough safe oxidation, there is corrosion. In this embodiment, that's all eliminated. Therefore, pre-plating is optimal.

Upon execution the end-user can just take the box, expand and grow it and then has all of their seams and everything done. All they have to do is set it up correctly. In other embodiments, there does not need to be a “tortured path” in the front. It moves all around to the sides, so one has this box that can be expanded or grown in any sigma or any RU or any depth, for a 17½ or 24 inch rack, for example. The box is expanded and the performance increases. All pre-plated, no screws, no assembly, a few rivets and its done. It's 100 percent reliable with zero assembly defects.

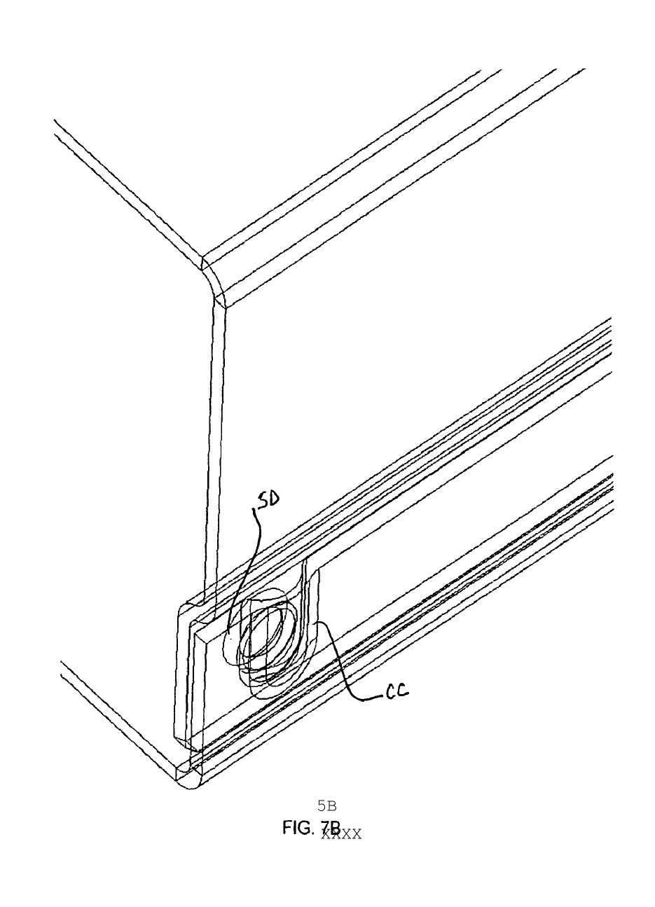

FIG. 4 refers to a sample three-dimensional EMI-shielding solution for an electronics enclosure in a basic embodiment, (such as referred to as the “three-dimensional tortured path solution”) with the “shell” or “scallop” embodiment of the invention. The three-dimensional patterns are formed or otherwise configured such that they are generally going the inside periphery of the edges, and the two parts FSE and FL come together and the “sinusoids” meet. All that is necessary for the implementation of the three-dimensional implementation of the invention is to “cut” or stamp the edge of the metal and make the same cut and they come together with a “30 gap” or something similar. The advantages of the primary embodiment of the invention include, inter alia, the fact that there does not need to be any contact and therefore no degradation over time. The parts FSE and FL don't have to make physical contact. Further advantages include that there are no tolerances to consider and there is nothing to deform.

The basic three-dimensional embodiment takes advantage of the manufacturing ease of using a two-part enclosure including a five-sided enclosure FSE with an interior volume IN for housing electronics and a flange FL, which fits into the five-sided enclosure upon completion. In this particular embodiment, either the box or the flange could be molded or cast, and thus “three-dimensional tortured path” or a TORTURE CHAMBER.™. is illustrated. In general, the electromagnetic interference cannot get in or out of the electronic enclosure. In the preferred embodiment shown, there is a (periodic) quarter sphere with a half cylinder-type shape IP, although, as can be appreciated by those skilled in the art, many other types of shapes would be sufficient for providing the necessary shielding, and some are briefly discussed below. In the illustration, the female three dimensional shapes FP in the “lid” or flange FL or mate with the male protrusions IP along the perimeter of the lid at the lid-to-box interface OE, which is generally the XY plane formed at the seam of the junction between the lid and the box (not shown), labeled as plane XY(#A). Even though there can be adequate spacing between the box FSE and the lid/flange FL, the shielding is provided well inside the allowable for the frequency that are generally desired for shielding.

The three-dimensional EMI-shielding solution includes an interior pattern IP of three-dimensional shapes which are stamped, cut, molded, extruded or otherwise configured into the five-sided enclosure FSE around the perimeter of the top or open edge OE. The interior pattern IP as being semi-spherical and “male” or protruding into the interior volume IN, however, in other embodiments the shapes could be reversed or “female” without necessarily departing from the spirit of the invention. The flange FL also includes a pattern that is “complementary” to each other such that the box and the phalange will seamlessly fit as well as provide sufficient EMI shielding. Further discussion regarding three-dimensional EMI shielding solutions is provided in PCT Application Publication WO/06-26758 (Oct. 1, 2006), assigned to the present applicant, and which is incorporated by reference for all purposes.

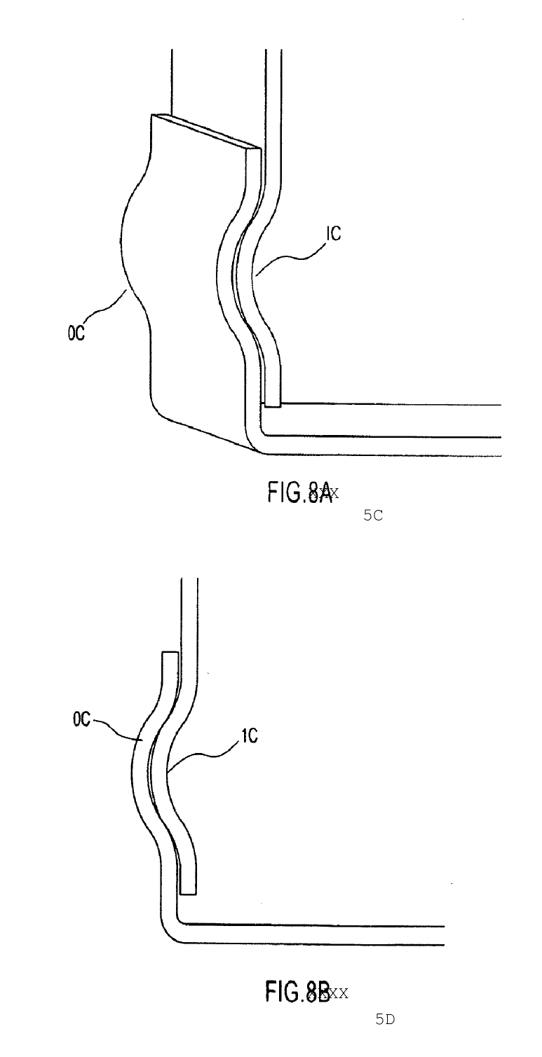

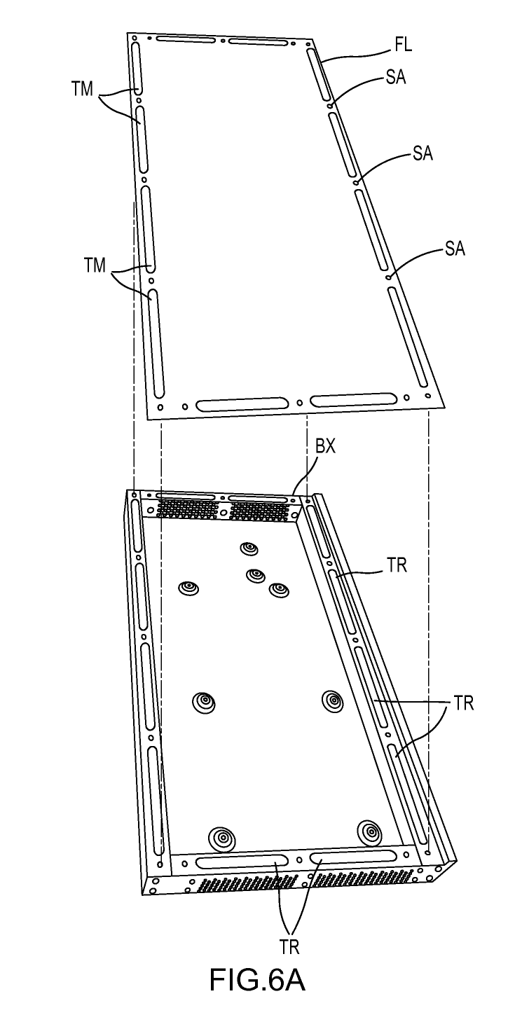

Referring now to FIG. 5A-B, a first “hybrid” embodiment of the electronics enclosure is shown, in which both two-dimensional and three-dimensional features provide EMI benefits. In this case, a simple overlap lid with a stepped-in base is seen, including the features that include the “dome” and the “dimple” which are used to provide the electromagnetic interference shielding. S-D is the dimple; C-C is the dome that fits over it. The gap would be a nominal perhaps 10 thousandths, whatever is appropriate for assembly, and that gap will dictate what the volumetric space that the wave would have to negotiate, and it would be reflected and absorbed as it traversed (traverses) between the cylinder structures and the dome structures, the dimple.

Referring again to FIG. 5A, structure SE-1 just reflects the top surface of the lid. Structure AC are the stepped-in bend corners of the base where it steps into accept the lid over top of it. The structure (configuration) referenced S2 reflects the side wall of the base. The structure referenced SF is, again, the bend channel as it bends in to allow the lid to come over the base. The waves are forced to negotiate between the side wall and the fringed-over section of the lid.

Referring again to FIG. 5B at the structure reference CC. Again, you see the semi-cylinder feature that's on the lid section, and at the structure referenced SD, you see the dimple that's in the base, again fitting the volumetric spherical space, “delta R sphere” space that the wave would have to negotiate. EMI entering this “space” would be reflected and absorbed, reflected and absorbed many, many times making it difficult to pass through that chamber. And the energy would be dissipated in heat and/or currents that are taken into the body of the chassis and fed off to fame (phonetic sp.) ground, and then ultimately office ground by whatever grounding system was implemented in this particular chassis.

FIGS. 5C-5D once again illustrate the assembly feature of the sprung section with the cylinder-in-cylinder part of the alternate embodiment using the 2D/3D combination of features. At reference structures CL1 and CL2 (contact lines), a situation is created in which there would be incidental contact along a line that was parallel to the interface of the base and the lid and further augmenting the EMI shielding of the enclosure. The “line contacts” shown in reference structures CL1/CL2 make physical grounding, and such as overlap for an assembly feature, the overlap for the wave guide, and then incidental contact along the lines into the page at CL1/CL2 for providing further EMI shielding.

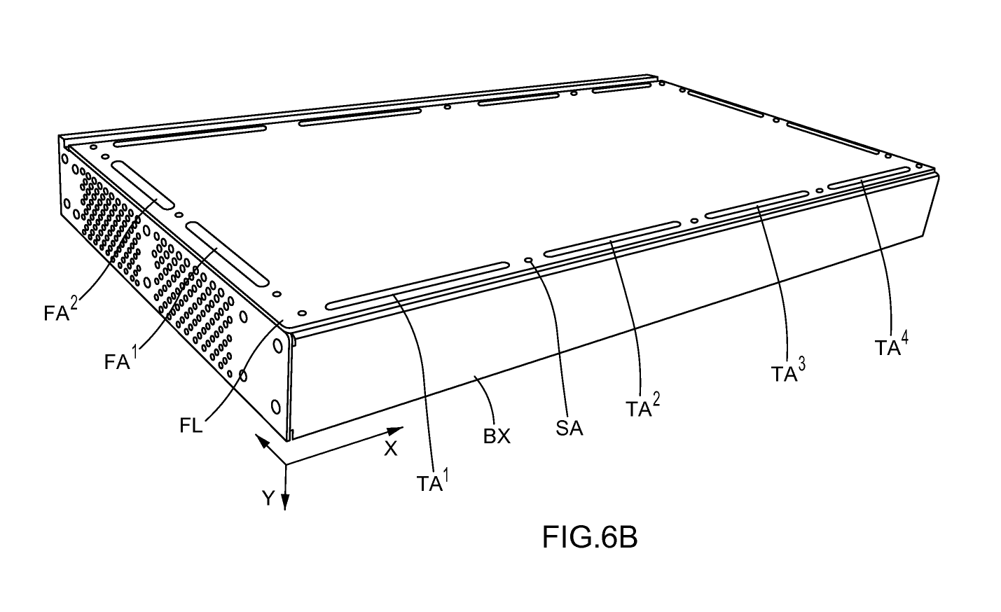

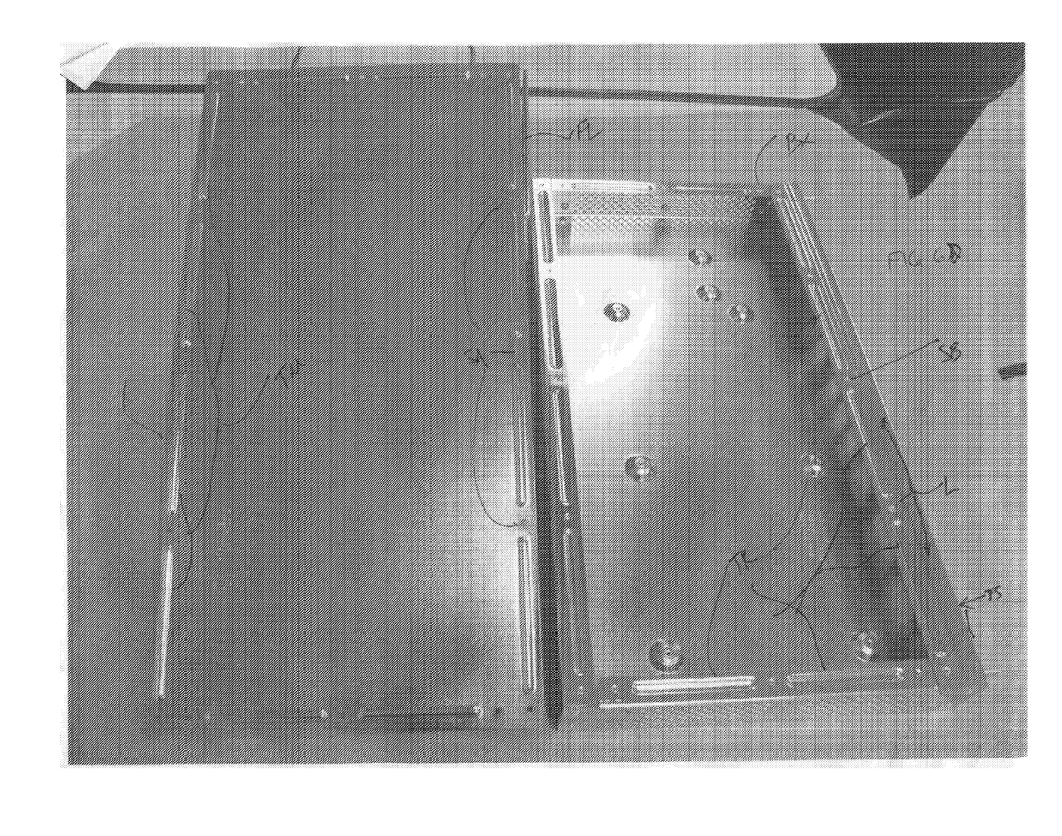

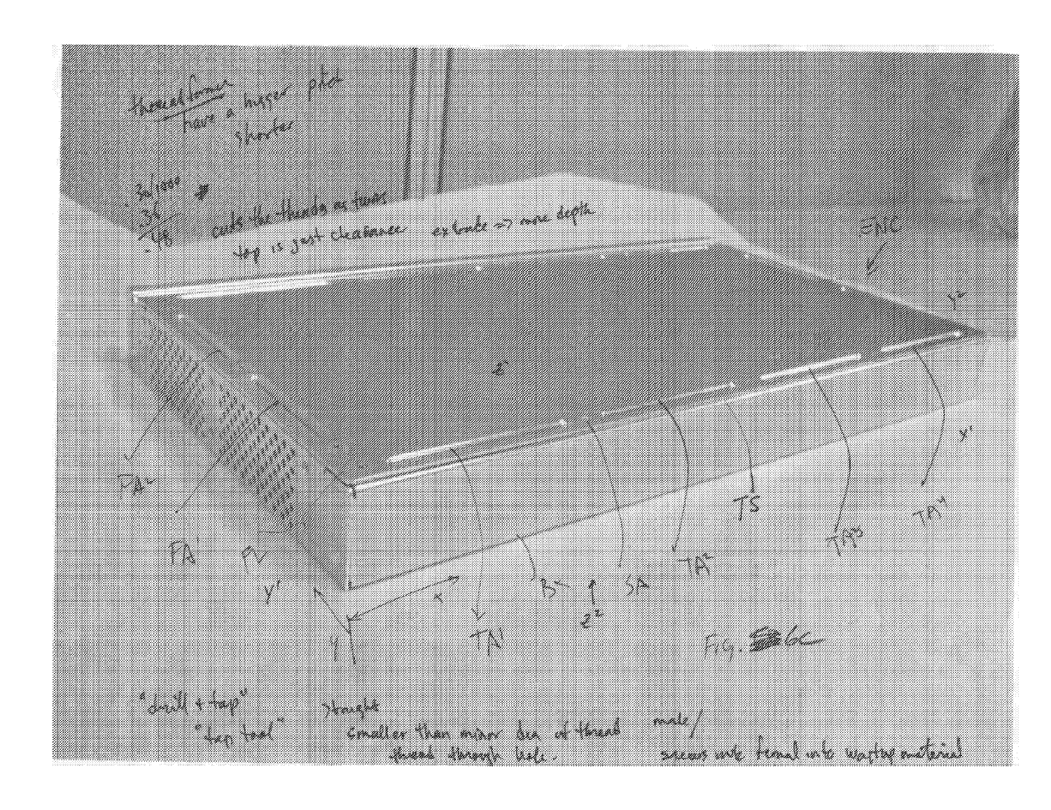

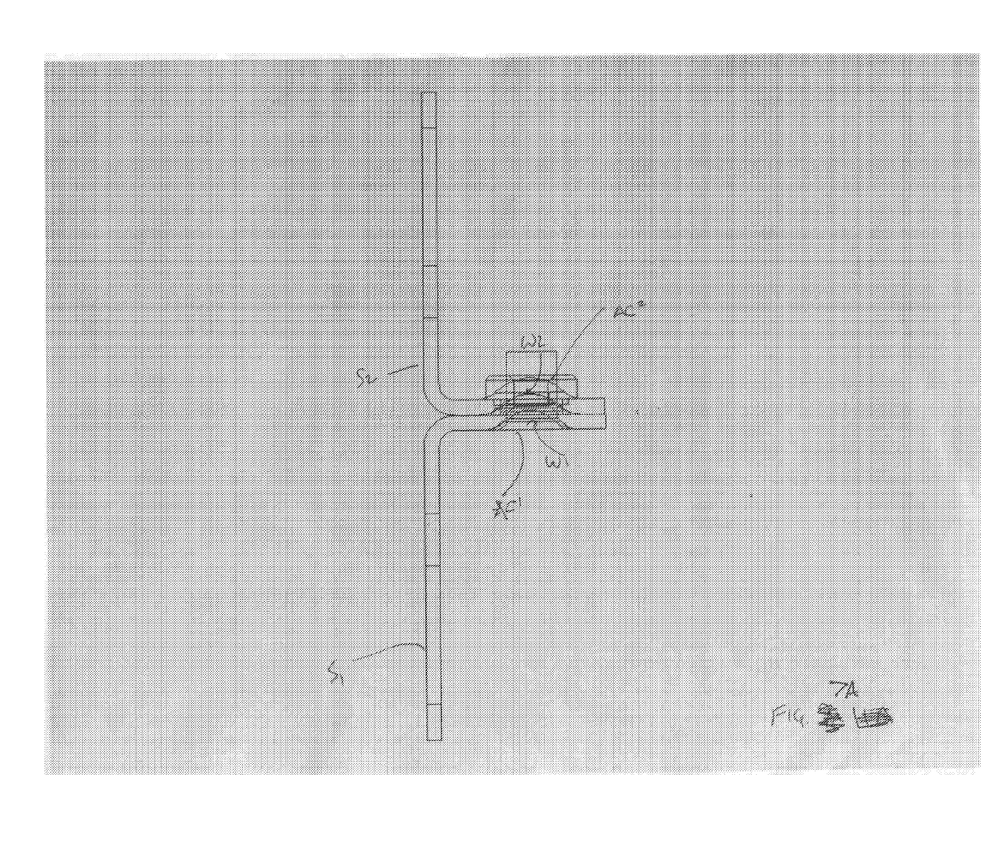

Referring now to FIGS. 6A and 6B, a main embodiment of the of the lid and box embodiment is illustrated as a low-cost electronics enclosure providing improved shielding. The invention is designed primarily to reduce or completely eliminate the use of gaskets in such enclosures, while still providing adequate EMI shielding. The invention takes advantage of the Applicant's “semi-cylinder in semi-cylinder” shielding features, in which mating semi-cylindrical channels (“attenuation troughs”) are formed into both a box BX and a lid FL, such that the semi-cylindrical channels provide both capacitance and conductive contact (and other electrical and mechanical advantages) when they are “mated.”

The troughs will also be referred to as “semi-cylinders,” although the actual shapes may be more like semi-elliptical cylinders or cylindroids. This description is made without departing from the scope of the invention. Referring now to FIG. 6A, a sample illustration of a main embodiment is shown. The main embodiment includes a box portion BX and a cover portion FL, which are designed to fit together as an enclosure for electronics. The box portion BX, which, like the top or lid portion FL is made out of a conductive material, usually mild steel in a preferred embodiment (but which may include other materials which will be discussed below), includes a lip L, which is formed in the box BX to extend inward from the top seam TS, which generally extends around the periphery of the top seam towards the interior of the box.

Formed into the lip structure L, are a series of semi-cylindrical shapes TR, shown as female (elliptical) cylinders in the embodiment. The semi-cylindrical shapes TR are formed around the periphery of the lip L, and in the illustration include 4 “equal” semi-cylinders along the length Lgth of the box, and 2 “equal” semi-cylinders along the width of the box. The semi-cylinders TR are separated by fastener threads SB.

The corresponding cover FL structure, has 4 “male” semi-cylinders configured TM into the length of flange, and 2 “male” semi-cylinders that are formed into the width.

FIG. 6B shows an “assembled” enclosure ENC, in which the semi-cylinder structures from the flange FL have fit into the semi-cylinder structures on the lip of the box to create EMI shielding or attenuating “cylinder-in-cylinder” structures TA(x)/TA(y) across the seam. The cylinder-in-cylinder structures TX(x)/TA(y) create both conductive electrical contact and capacitance along the entire length of the structure. The detail of these structures is discussed below. In general, the cylinder-in-cylinder structure at least partially crosses the “plane” of the seam where the box intersects the flange of the top xy seam. However, it is not required to do so to take advantage of the theory behind these embodiments.

In addition, the enclosure has two sets of ventilation structures VS1 and VS2 on the two sides yz1 and yz2 of the box. These ventilation structures VS1 and VS2 are generally known in the art.

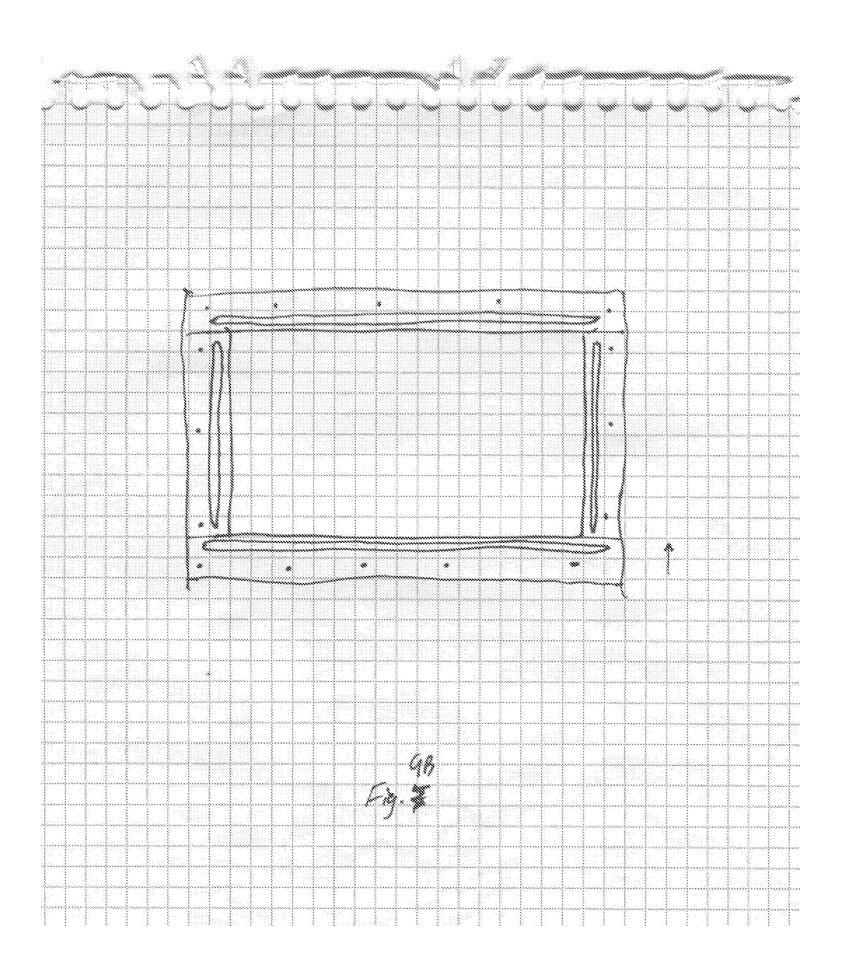

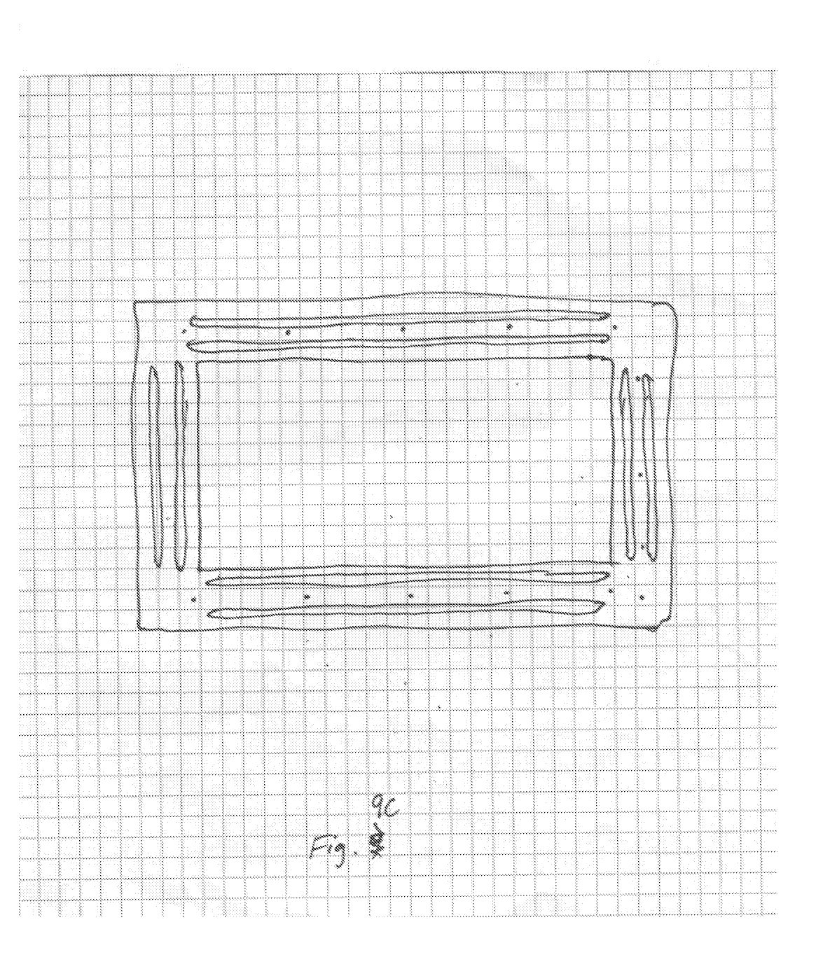

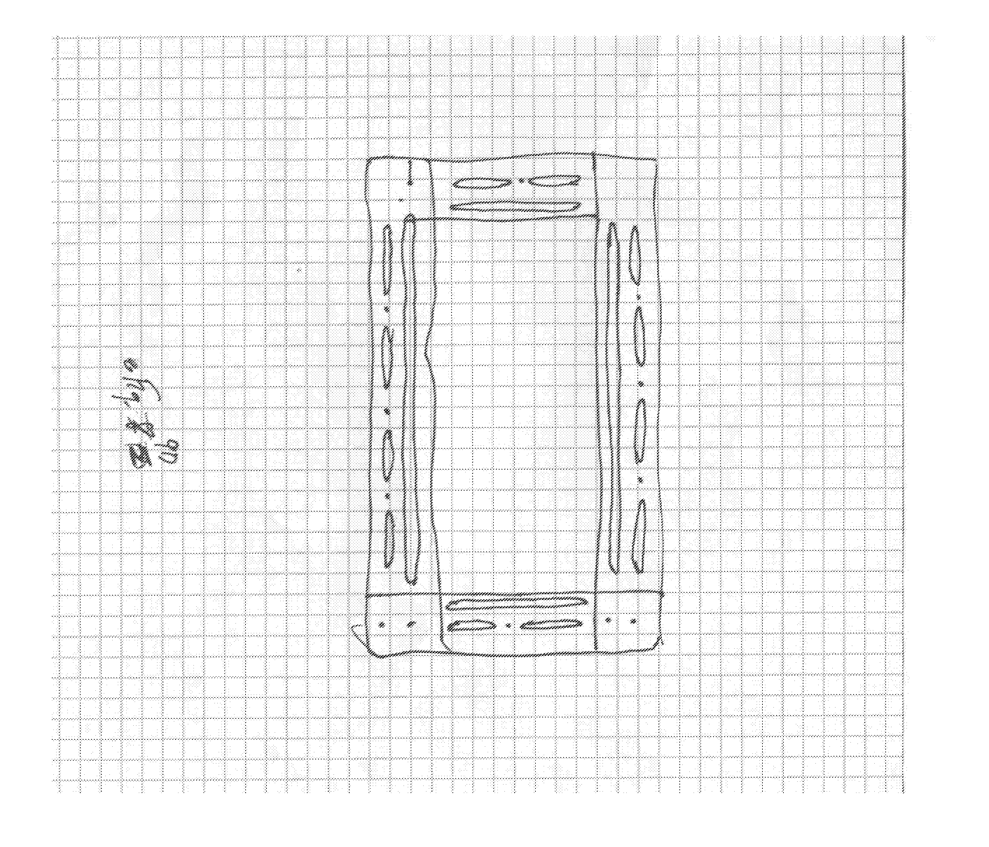

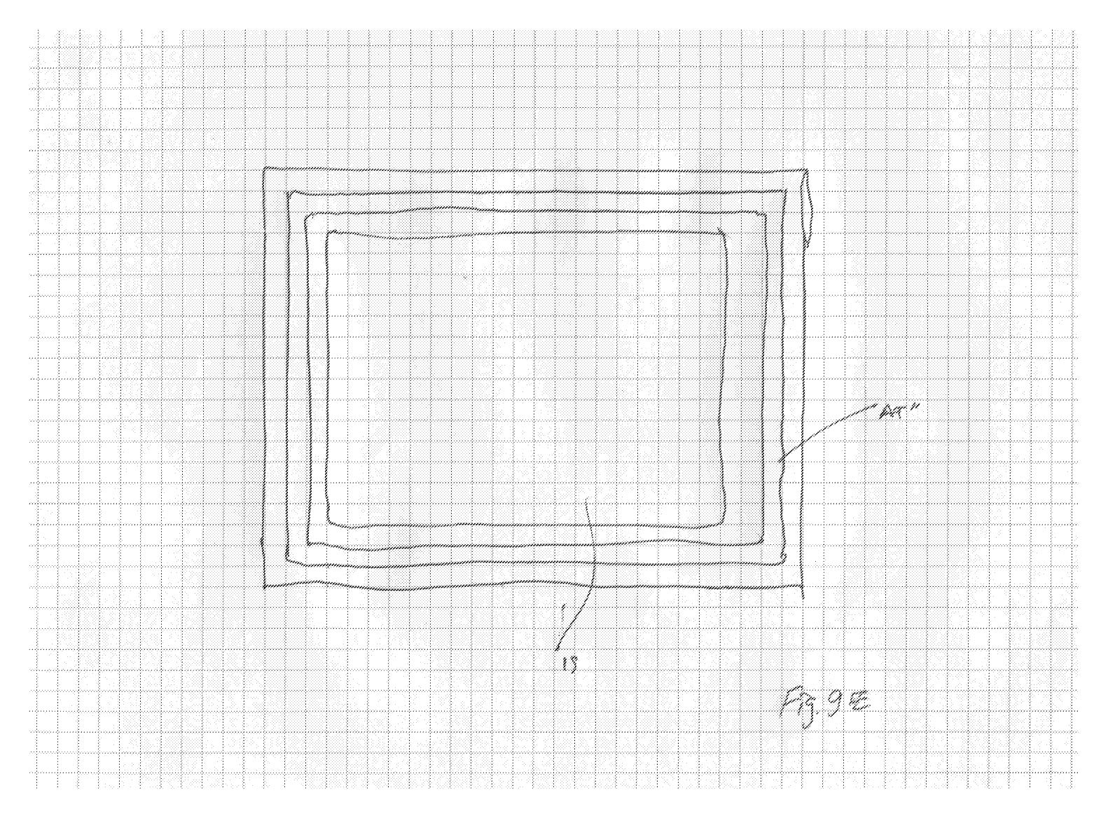

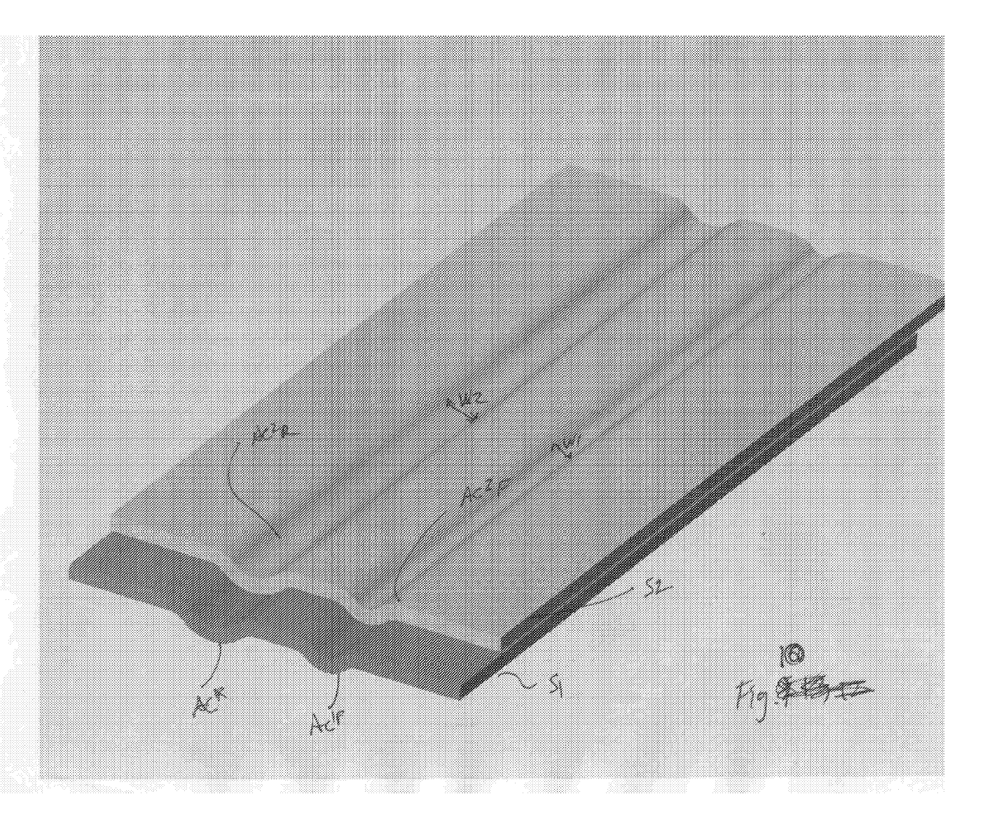

In general, the illustrations in FIGS. 6A and 6B are shown and have been configured due to manufacturing and machining standards, as well as convenience for the end users, and considers the tolerances for the material, especially for the lip structure L and the fastening system of the box. For example, there are 16 fastener threads on the lip L structure. However, there are no limitations of the potential configurations of the invention that would prove effective at shielding electromagnetic equipment from harmful EMI. The lip L includes the semi-cylinder structures TA1 . . . TAx in the center in the illustrative embodiment. However, in other embodiments shown in subsequent illustrations (FIGS. 9a-11), there are different configurations that may be more appropriate for different end uses. Also, complex needs for additional EMI shielding may require additional or alternate semi-cylindrical attenuation structures, as are illustrated and discussed subsequently.

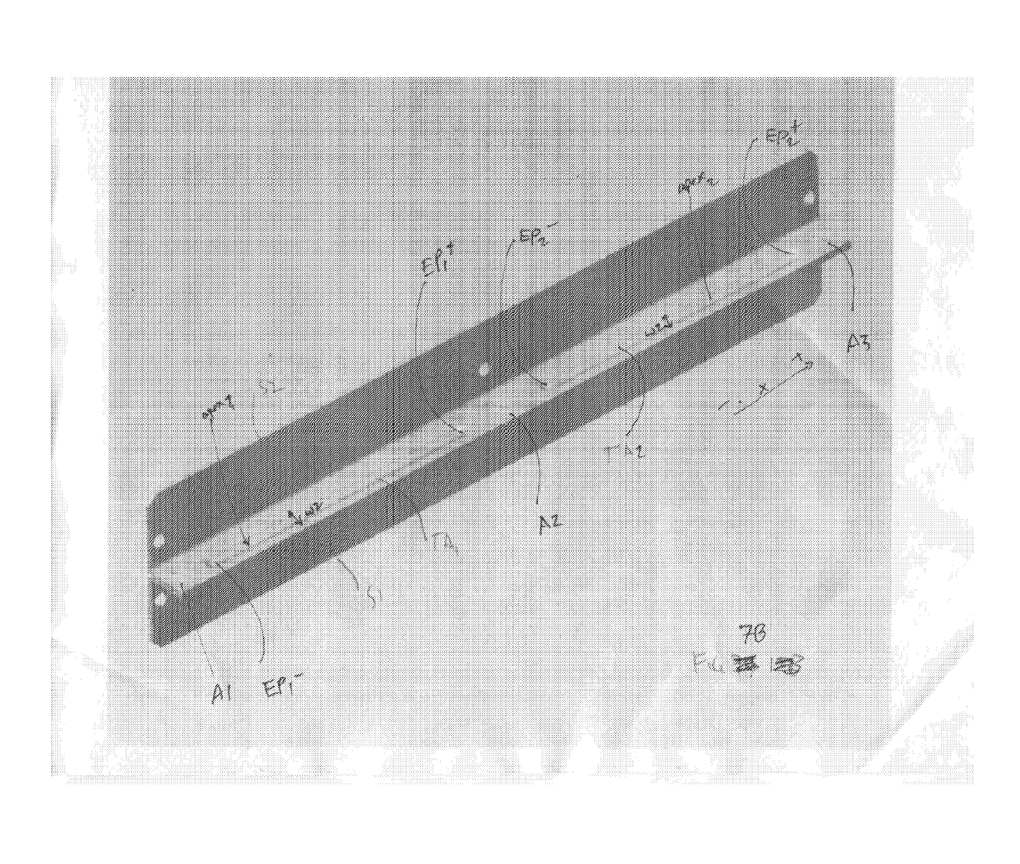

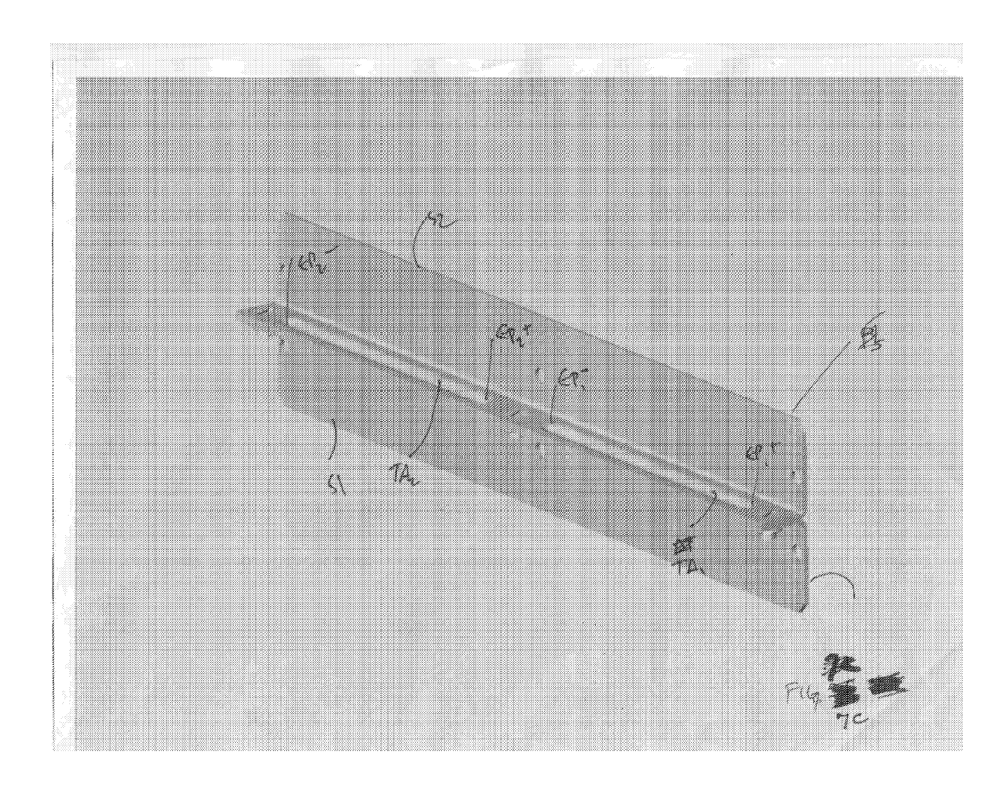

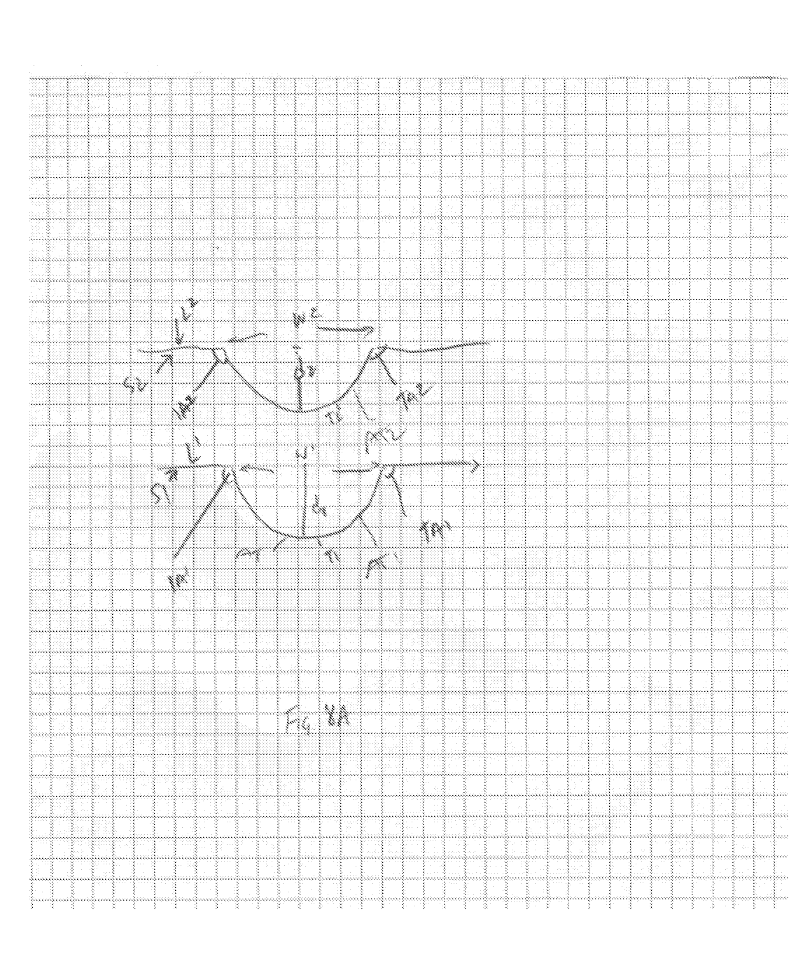

FIGS. 7A-C illustrate detail of the semi-cylinder-in-semi-cylinder, or attenuation troughs of the main embodiment of the invention. The semi-cylinder-in-semi-cylinder attenuation structures both provide capacitance and conductance which in turn provides EMI attenuation and shielding. Depending on the configuration of embodiment of the invention, the troughs are formed such that there is a high degree of electrical contact between the bottom of the top trough and the top of the bottom trough, usually in a “line” as provided by design, but at least in multiple points of contact as provided in practice over the life of product. Although only a single point of contact between the two structures is required to provide the conductivity, the more the contact between the two surfaces, the better the electromagnetic shielding. Thus, increased torque of the fastener can improve the performance of the invention by improving electrical contact between the upper and lower semi-cylindrical channels, as long as the torque is within the safety margin of the product, over the lifetime of the product.

FIG. 7A illustrates a first detail of the semi-cylinder-in-semi-cylinder system, as illustrated in FIGS. 6A-B. The lower conductive sheet is formed with a first semi-cylinder or set of semi-cylinders AC1 . . . ACx. In some embodiments, as those shown in FIGS. 6A and 6B there will be multiple intermittent semi-cylindrical channels. In other embodiments discussed below, there will be a single semi-cylindrical channel (not shown).

As shown in FIGS. 7B and C, each semi-cylinder trough AC1 . . . ACx is terminated with a “quarter-sphere” shape rounding off the semi-cylinder trough. In practice, the shape will generally be “less” than a quarter sphere, but is not limited to this. The EMI shielding advantages of a having a partial sphere incorporated into a electronics enclosure are discussed in U.S. Pat. No. 7,342,184, issued Mar. 11, 2008 to the Applicant, and U.S. Pat. No. 7,995,355, issued Aug. 9, 2011 to the Applicant, and both of which are incorporated by reference.

The semi-cylinder troughs formed into the top conductive sheet are slightly different in shape per the “common surface” than the bottom semi-cylinder troughs in a preferred embodiment. The advantage of this is threefold. (1) If the top semi-cylinder is slightly shorter in length that the bottom semi-cylinder, the semi-cylinder structures will not be inclined to “stick;” (2) the wear will be less over the lifetime of the product and the semi-cylinder troughs will maintain enough points of contact to be effective; and (3) there will be a greater tolerance from deformation due to torque from the attachment screws over time. Thus, the top and bottom semi-cylinders form an attenuation trough TA1 . . . TAx.

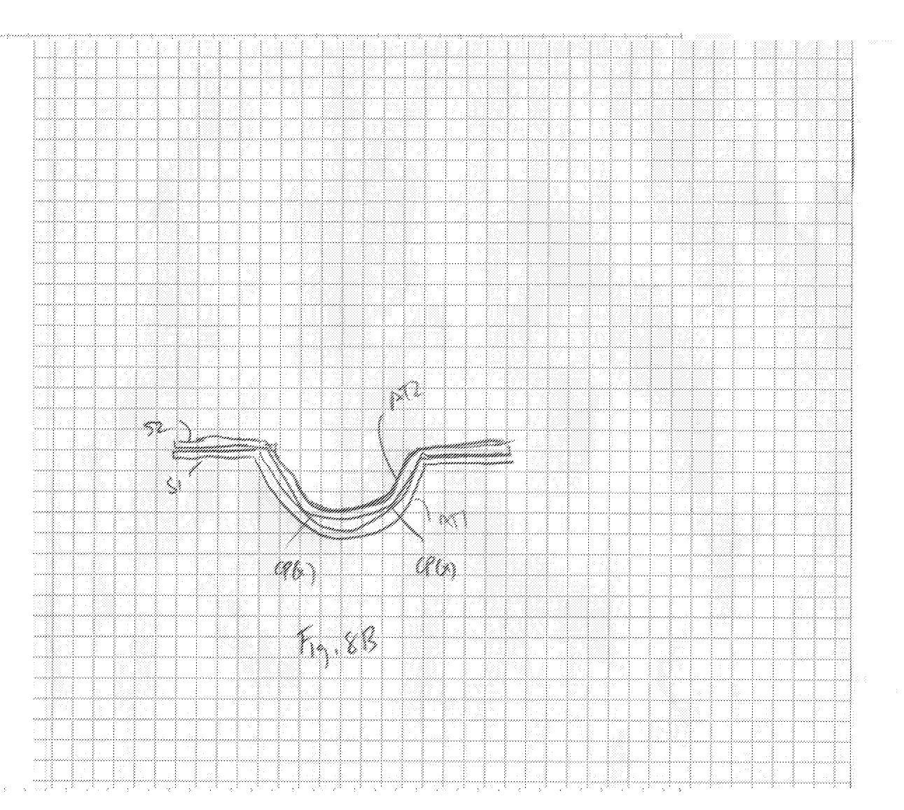

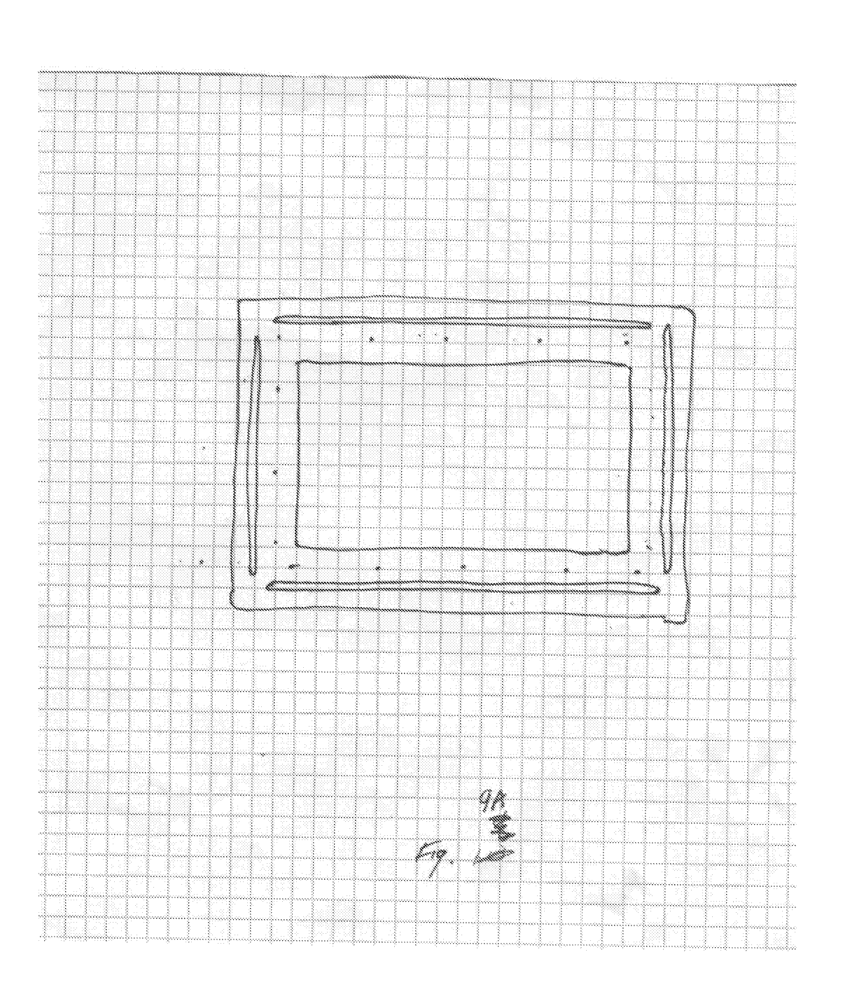

FIGS. 8A and B illustrate the fundamental shaping of the EMI-attenuation system in the main embodiment. FIG. 8A illustrates the primary embodiment as shown and implemented in FIGS. 6A-7C. FIG. 8A shows the two conductive sheets S1 and S2 each with a side view of an attenuation trough AT1 and AT2. Each attenuation trough has dimensions d1/d2 (depth), w1/w2 (width), IA1/IA2 (initial angle from lip), TA1/TA2 (final angle from lip) and t1/t2 (thickness of material). It is anticipated that the three-dimensional aspect of the attenuation troughs AT1/AT2 will be roughly and elliptic cylinder, but the dimensions of each will vary slightly to optimize the invention. Obviously, the thickness of the material t1/t2 must be taken into account when design the dimensions of the attenuations troughs, but other factors must be taken into account.

For example, as shown in FIG. 8B, if the two attenuation troughs AT1/AT2 are slightly different in dimension, there is still the desired line/multiple points of contact CP(x) over the life of the enclosure, but if the first attenuation trough AT1 is slightly larger in depth d1 and width w1, but has a smaller initial angle IA1 and terminal angle TA1 from the lip L1, the upper attenuation trough AT2 will contact the lower attenuation trough AT1 to provide the desired conduction and allow for easy removal of the lid L without causing serious deformation to either of the attenuations troughs AT1/AT2 preserving the EMI attenuating properties.

FIGS. 9A-E illustrate sample alternate configurations of the cylinder-in-cylinder structural placement on the box and flange embodiment. FIG. 9A illustrates an assembled box in an alternate embodiment. In FIG. 9A, the semi-cylinder structures are a single continuous structure (as opposed to the “intermittent structure” shown in FIGS. 6A and 6B). However, the semi-cylinder “troughs” are placed further into the lip structure L′ so that the attachment structures do not interrupt the effect of cylinder-in-cylinder attenuation. However, placing additional stresses on the lip structure L′ is only practical insofar as the additional shielding is needed.

FIG. 9B illustrates another alternate configuration of the invention in which the semi-cylindrical channels are continuous along all the sides and placed in front of the attachment structures AS.

FIG. 9C illustrates another alternate embodiment, in which there are two rows of cylinder-in-cylinder structures one continuous cylinder-in-cylinder structure formed into the rear of the lip “behind” the intermittent cylinder-in-cylinder structure which straddle the attachment structures AS. FIG. 9D illustrates yet another alternate embodiment in which there are both a set of intermittent semi cylinder-in-semi cylinder structures straddle the attachment structures in the front part of the lip structure L, and a continuous cylinder-in-cylinder attenuation structure is “behind” the front row.

FIG. 9E illustrates yet another alternate embodiment in which there is a continuous attenuation trough around the perimeter of the enclosure. The continuous attenuation trough(s) AT″ will likely provide for more complex manufacturing process, but also provide superior EMI attenuation as there are fewer “gaps.” This “picture frame” embodiment would be more suitable for certain end-use applications.

FIGS. 9A-E simply illustrate samples of how the attenuation features of the electronic enclosure may operate under differing configurations. The exemplars shown are meant to be illustrative and are certainly not limited to the examples show.

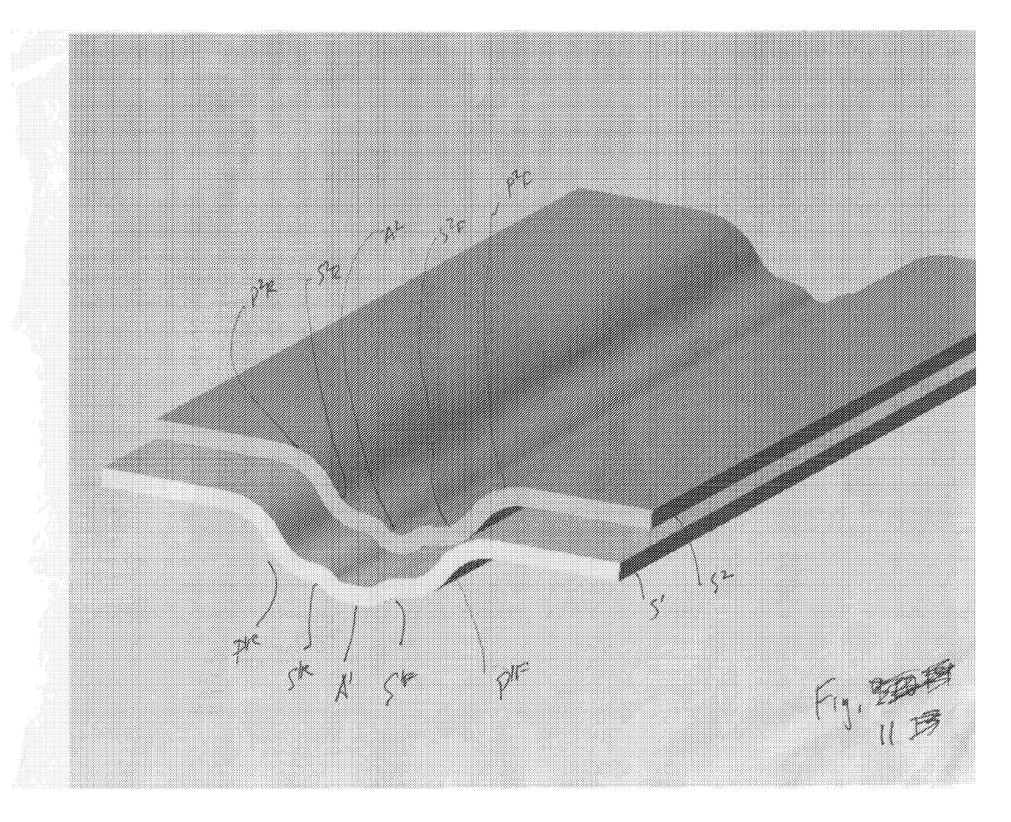

Referring now to FIG. 10, an alternate embodiment is shown as the trough-in-trough attenuations structures are shown in a parallel (or series) configuration in which the two semi-cylinder-in-semi-cylinder sets have different properties. Bottom sheet S1 is formed with two semi-cylinders AC1(f) and AC1(r) which have two different widths WC1(f) and WC1(r), thus providing for various advantages in which additional EMI attenuation may be provided by changing the parameters which were discussed in FIGS. 8a-b above.

Referring now to FIG. 11 a second alternate configuration of the attenuation troughs is shown. In FIG. 11 the attenuation troughs A1/A2 of the two conductive sheets S1/S2 are also formed with secondary shapes that provide additional optional conductive contact points between the sheets.

The above illustrations are meant to be exemplary only. Many other configurations of the invention are contemplated, and instead the invention is meant to be defined by the claims below.

We claim:

1. An electronics enclosure comprising: a box formed from electrically conductive material and a cover formed from electrically conductive material;
said box including a lip extending towards an inward space extending from a top seam around the periphery of an open end of said box, said lip including a first set of semi-elliptic cylindrical shapes formed into said lip;
a cover including a second set of semi-elliptic cylindrical shapes configured to be placed into said first set of semi-elliptic cylindrical shapes in said box, when said cover is placed onto said box;
wherein when said second set of semi-elliptic cylinders is placed into said first set of semi-elliptic cylinders, there are multiple points of contact between a bottom surface of said second set of semi-elliptic cylinders and a top surface of said first set of semi-elliptic cylinders, whereby electromagnetic interference is reduced by both the conductance caused by said multiple points of contact and a capacitance caused by said semi-elliptic cylinder in semi-elliptic cylinder surfaces.

2. The enclosure as recited in claim 1, wherein said semi-elliptic cylindrical shapes in said box extend downward.

3. The enclosure as recited in claim 1, wherein said first set of semi-elliptic cylindrical shapes are formed at a first depth and width and a second set of semi-elliptic cylindrical shapes is formed at a second depth and width.

4. The enclosure as recited in claim 3, wherein said first set of semi-elliptic cylindrical shapes have a slightly greater depth and width that said second set of semi-elliptic cylindrical shapes.

5. The enclosure as recited in claim 4, wherein said difference in depth created a compression in said male semi-elliptic cylindrical shape and a tension in said female semi-elliptic cylindrical shape.

6. The enclosure as recited in claim 5, wherein said tension and said compression do not provide a binding force between said box and said lid greater than 1 kg.

7. An electronics enclosure comprising: a box formed from electrically conductive material and a cover formed from electrically conductive material;
said box including a lip extending towards an inward space extending from a top seam around the periphery of an open end of said box, said lip including a first semi-elliptic cylindrical shape formed into said lip;
a cover including a second semi-elliptic cylindrical shape configured to be placed into said semi-elliptic cylindrical shape in said box, when said cover is placed onto said box;
wherein when said semi-elliptic cylinder is placed into said first semi-elliptic cylinder, there are multiple points of contact between a bottom surface of said semi-elliptic cylinder and a top surface of said semi-elliptic cylinder, whereby electromagnetic interference is reduced by both the conductance caused by said multiple points of contact and a capacitance caused by said semi-elliptic cylinder in semi-elliptic cylinder surfaces.

8. The electronics enclosure as recited in claim 7, wherein said electrically-conductive material is steel.

9. The electronics enclosure as recited in claim 7, wherein said first semi-elliptic cylinder has a slightly larger radius than said second semi-elliptic cylinder.

10. The electronics enclosure as recited in claim 9, wherein said differences is said first and said second semi-elliptic cylindrical radii create a tension between said box and said lid.
